(19) United States
(12) Patent Application Publication
(10) Pub. No.: US 2026/0198302 A1
(43) Pub. Date: Jul. 9, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Chieh-En CHEN, Tainan City (TW); Chen-Hsien LIN, Tainan City (TW); Shyh-Fann TING, Tainan City (TW)

(21) Appl. No.: 19/009,353

(22) Filed: Jan. 3, 2025

(51) Int. Cl. H01L 23/522; H10F 39/00; H10F 39/18

(52) U.S. Cl. CPC H10W 20/496; H10F 39/011; H10F 39/182; H10F 39/809; H10F 39/811

(57) ABSTRACT

A top electrode layer of a capacitor structure of a pixel sensor is connected to a bottom contact of an interconnect layer of a semiconductor device. The bottom contact is located at the bottom of the capacitor structure and connects the top electrode layer to a reset voltage source and to a reset transistor of the pixel sensor without the use of additional vias, metallization layers, and/or other conductive interconnect structures that extend alongside the capacitor structure. As a result, the lateral footprint of the capacitor structure can be increased, which increases capacitor area of the capacitor structure.

### BACKGROUND

A complementary metal oxide semiconductor (CMOS) image sensor may include a plurality of pixel sensors arranged in a pixel sensor array. A pixel sensor of the CMOS image sensor may include a photodiode configured to convert photons of incident light to a photocurrent of electrons. The magnitude of the photocurrent is based at least in part on the intensity of the incident light. Accordingly, if the pixel sensors in the pixel sensor array are capable of sensing incident light across a broad range of intensity, a high range of brightness and contrast may be achieved in images and/or video generated by the CMOS image sensor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of an example semiconductor device described herein.

FIGS. 2A-2T are diagrams of an example implementation of forming a semiconductor device described herein.

FIGS. 3A-3E are diagrams of an example implementation of forming a semiconductor device described herein.

FIGS. 4A-4N are diagrams of an example implementation of forming a semiconductor device described herein.

FIG. 5 is a circuit diagram of an example implementation of a capacitor structure described herein.

FIG. 6A is a diagram of an example semiconductor device described herein.

FIG. 6B is a diagram of an example circuit for a pixel sensor described herein.

FIG. 7 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a pixel sensor may be limited in the number of photons of incident light that can be absorbed before reaching saturation of the pixel sensor. “Saturation” refers to a level of photon absorption past which additional photons of light cannot be absorbed by the pixel sensor. Saturation of the pixel sensor results in a limited dynamic range for the pixel sensor because additional brightness and color information cannot be obtained from further absorption of photons.

The amount of photocurrent charge that can be stored in a pixel sensor before reaching saturation may be referred to as the full well capacity (FWC) of the pixel sensor. The full well capacity of the pixel sensor may be based at least in part on the size (e.g., the depth, the width, the volume) of the photodiode of the pixel sensor and/or the shape of the photodiode, among other examples. While increasing the size of the photodiode may increase the full well capacity of the pixel sensor, doing so may come at the expense of decreasing the density of pixel sensors in the pixel sensor array, which may reduce the resolution of the pixel sensor array.

To increase the FWC of a pixel sensor, an image sensor device (e.g., a complementary metal-oxide-semiconductor (CMOS) image sensor device) may include a capacitor structure that is configured to store charge associated with a photocurrent that is generated by the pixel sensor prior to the charge being transferred to a floating diffusion node associated with the pixel sensor. The photocurrent may be transferred from the pixel sensor to the capacitor structure, which enables the pixel sensor to generate more charge for the photocurrent than if the photocurrent were wholly stored in the photodiode and/or in the floating diffusion node. Thus, the capacitor structure may increase the FWC of the pixel sensor, which may enable a higher range of brightness and/or contrast (e.g., high dynamic range (HDR)) to be achieved in images and/or video generated by the pixel sensor array. The capacitor structure is designed to achieve a small lateral footprint for the capacitor structure, and may include a metal-insulator-metal (MIM) layer stack in which bottom electrode layers and top electrode layers are arranged in an alternating manner and separated by an insulator layer.

The pixel sensor may be a lateral overflow integration capacitor (LOFIC) pixel sensor that includes an overflow gate and an overflow capacitor including the capacitor structure. The overflow capacitor may be electrically coupled to the floating diffusion node through the overflow gate such that photocurrent may be transferred from the floating diffusion node to the overflow capacitor for temporary storage. A reset gate may be used to remove or discharge the photocurrent from the floating diffusion node and/or from the overflow capacitor by applying a reset voltage to the floating diffusion node and/or the overflow capacitor to “reset” the floating diffusion node and/or the overflow capacitor (e.g., by draining any residual charge in the floating diffusion node and/or the overflow capacitor).

A capacitor structure of a LOFIC pixel sensor may be included in an interconnect layer (e.g., a back end region or back end of line (BEOL) region) of a semiconductor device. Vias, metallization layers, contacts, and/or other conductive structures in the interconnect layer may connect the capacitor structure to one or more transistors of the LOFIC pixel sensor that are located in an underlying device layer (e.g., a front end region or front-end-of-line (FEOL) region) of the semiconductor device. To connect a top electrode layer of the capacitor structure to the transistor(s) of the LOFIC pixel sensor, a top connection may be formed to the top electrode layer at the top of the capacitor structure, and additional vias, metallization layers, and/or other conductive interconnect structures that extend alongside the capacitor structure connect the top connection to the transistor(s).

The top connection and the additional vias, metallization layers, and/or other conductive interconnect structures that extend alongside the capacitor structure limit the size, and therefore the capacitance, of the capacitor structure, in that these structures limit the lateral size of the capacitor structure. As a result, the limited capacitance of the capacitor structure may be insufficient to achieve a high dynamic range (HDR) for the pixel sensor.

Moreover, formation of the top connection may result in damage to the top electrode layer, such as during an etching process to form a recess in which the top connection is to be formed. In particular, a plasma-based etch may be performed, which may result in plasma charge damage to the top electrode layer.

In addition, capacitor structures in a pixel sensor array may be connected to a reset voltage source on a per-pixel basis. This results in further additional conductive structure routing in the interconnect layer, which increases the time required to reset the capacitor structures (e.g., because of an increased resistor-capacitor (RC) time constant for the capacitor structures), which results in reduced operational speed for the pixel sensor array and lower frame rates (e.g., frames per second (FPS)) for the pixel sensor array.

In some implementations described herein, a top electrode layer of a capacitor structure of a pixel sensor (e.g., a LOFIC pixel sensor) is connected to a bottom contact (e.g., as opposed to a top connection) of an interconnect layer of a semiconductor device. The bottom contact is located at the bottom of the capacitor structure and connects the top electrode layer to a reset voltage source and to a reset transistor of the pixel sensor without the use of additional vias, metallization layers, and/or other conductive interconnect structures that extend alongside the capacitor structure. As a result, the lateral footprint of the capacitor structure can be increased, which increases capacitor area of the capacitor structure.

The use of the bottom contact also prevents plasma charge damage to the top electrode layer in that the top electrode layer is formed on the bottom contact as opposed to a top connection being formed on the top electrode layer. Thus, the plasma charge damage that might otherwise be caused during an etching process to form a recess for the top connection is avoided. The connection of the top electrode layer to the bottom contact also facilitates implementation of a local reset function for the pixel sensor and other pixel sensors in a pixel sensor array of the semiconductor device. For example, the bottom connection can be part of an existing metallization loop or part of an added metallization layer to connect capacitor structures of the pixel sensors to the reset voltage source so that the capacitor structures can be reset locally with a reduced RC time constant, resulting in faster capacitor reset speeds and increased frame rates in comparison to other pixel sensor arrays. In some implementations, in addition to providing a bottom contact structure, capacitance is further increased by using a trench capacitor structure with a second MIM structure on a first MIM structure.

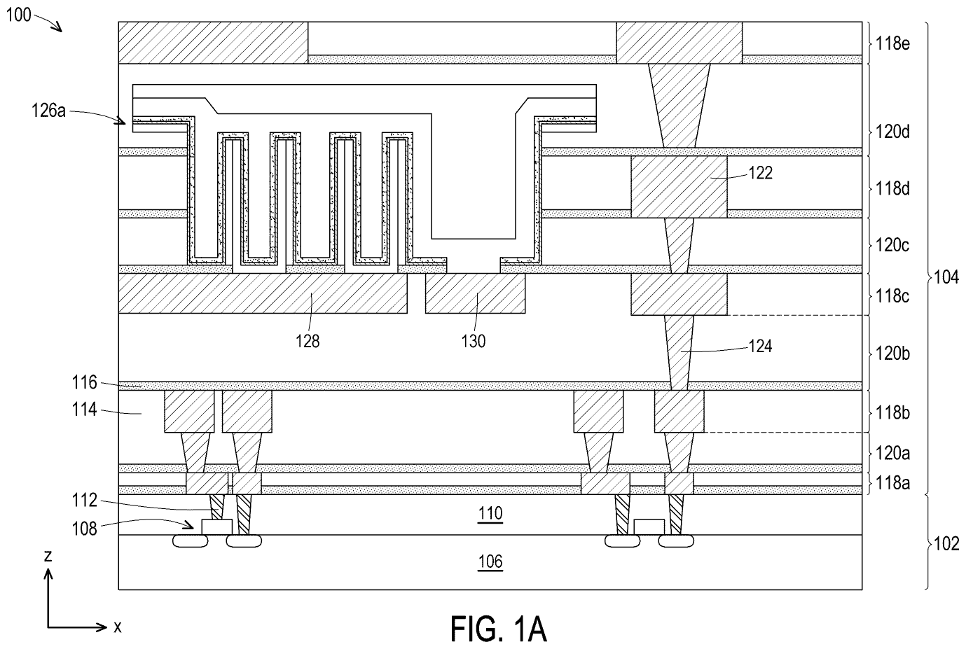

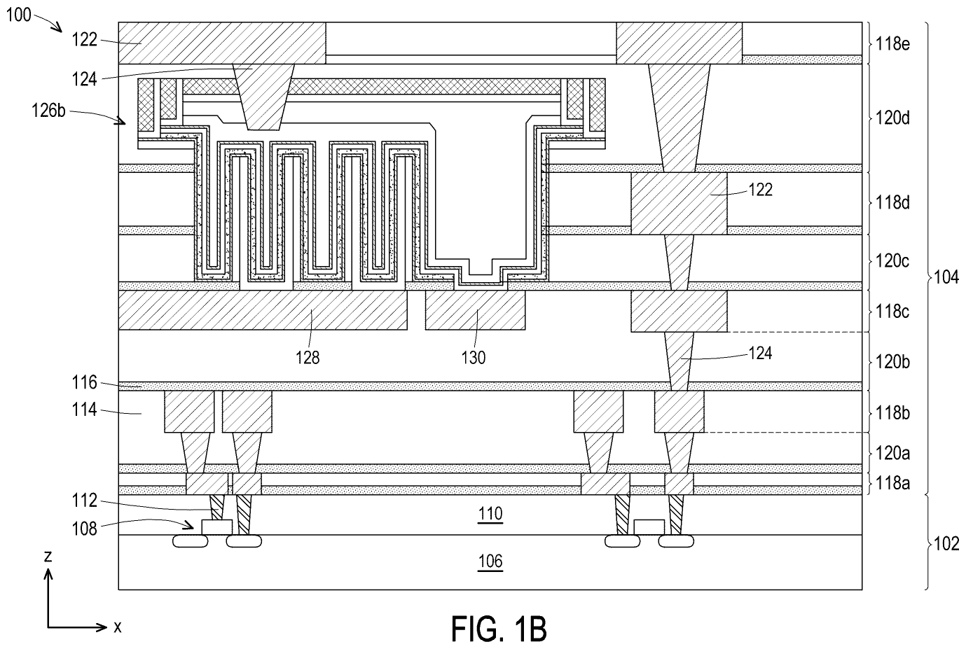

FIGS. 1A and 1B are diagrams of an example semiconductor device 100 described herein. The semiconductor device 100 may include system on chip (SoC) device, a logic device such as a central processing unit (CPU) or a graphics processing unit (GPU), a memory device (e.g., a high bandwidth memory (HBM) device), an image sensor device (e.g., a complementary metal-oxide-semiconductor (CMOS) image sensor device), and/or another type of semiconductor device.

FIGS. 1A and 1B illustrate cross-section views of the semiconductor device 100. As shown in FIGS. 1A and 1B, the semiconductor device 100 may include a device layer 102 and an interconnect layer 104 arranged in a z-direction in the semiconductor device 100 with respect to the device layer 102. For example, the interconnect layer 104 may be located above the device layer 102. As another example, the interconnect layer 104 may be located below the device layer 102.

The device layer 102 may also be referred to as a front end region or front end of line (FEOL) region of the semiconductor device 100. The interconnect layer 104 may also be referred to a back end region or back end of line (BEOL) region of the semiconductor device 100, and may include conductive structures that are arranged to carry signals and/or provide power distribution throughout the semiconductor device 100. In some implementations, the semiconductor device 100 includes interconnect layers 104 above and below the device layer 102. A first interconnect layer 104 on a first side of the device layer 102 may be used for signal propagation throughout the semiconductor device 100, and a second interconnect layer 104 on an opposing second side of the device layer 102 may be used for power distribution in the semiconductor device 100.

The device layer 102 includes a substrate 106 of the semiconductor device 100. The substrate 106 may correspond to a portion of a semiconductor wafer on which the semiconductor device 100 is formed. The substrate 106 may include a silicon (Si) substrate, a substrate formed of a material including silicon, a III-V compound semiconductor material substrate such as gallium arsenide (GaAs), a silicon on insulator (SOI) substrate, or another type of substrate. The substrate 106 may extend in an x-direction and/or in a y-direction in the semiconductor device 100 such that the top and bottom surfaces of the substrate 106 are approximately orthogonal to the z-direction in the semiconductor device 100.

Integrated circuit devices 108 may be included in and/or on the substrate 106 in the device layer 102 of the semiconductor device 100. The integrated circuit devices 108 may include front end transistor structures (e.g., front end planar transistor structures, front end fin field effect transistor (finFET) structures, front end gate all around (GAA) transistor structures), pixel sensors, capacitors, resistors, inductors, photodetectors, transceivers, transmitters, receives, optical circuits, and/or other types of front end semiconductor devices.

A front end transistor structure may include a plurality of source/drain regions, which may correspond to doped regions of the substrate 106, separated by a channel region in the substrate 106. In some implementations, the source/drain regions are doped with a first type of dopant (e.g., a p-type dopant such as boron (B) and/or gallium (Ga), an n-type dopant such as phosphorous (P) and/or arsenic (As)), and the channel region is doped with a second type of dopant that is different from the first type of dopant. The front end transistor structure may include a gate structure over and/or around the channel region. A gate dielectric layer of the front end transistor structure may be included between the gate structure and the channel region. The gate structure may include a polysilicon gate, a metal gate with a high dielectric constant (high-k) gate dielectric layer such as hafnium oxide (HfOₓ such as HfO₂), and/or another type of gate structure.

A dielectric layer 110 is included over the substrate 106. The dielectric layer 110 includes an interlayer dielectric (ILD) layer, an etch stop layer (ESL), and/or another type of dielectric layer. The dielectric layer 110 includes dielectric material(s) that enable various portions of the substrate 106 and/or the integrated circuit devices 108 to be selectively etched or protected from etching, and/or to electrically isolate the integrated circuit devices 108 in the device layer 102. The dielectric layer 110 includes a silicon nitride (SiₓN_{y}), an oxide (e.g., a silicon oxide (SiOₓ) and/or another oxide material), and/or another type of dielectric material.

The dielectric layer 110 may extend in the x-direction and/or in the y-direction in the semiconductor device 100. Contacts 112 (e.g., source/drain contacts, gate contacts) may extend through the dielectric layer 110 and between the integrated circuit devices 108 and the interconnect layer 104. The contacts may electrically connect the integrated circuit devices 108 to the interconnect layer 104. The contacts 112 may include vias, plugs, and/or another type of elongated electrically conductive structures. The contacts 112 may include tungsten (W), cobalt (Co), ruthenium (Ru), titanium (Ti), aluminum (Al), and/or gold (Au), among other electrically conductive materials.

The interconnect layer 104 includes a plurality of dielectric layers (e.g., back end dielectric layers) that are arranged in a direction (e.g., the z-direction) that is approximately perpendicular to the top surface of the substrate 106. The dielectric layers may include ILD layers 114 and ESLs 116 that are arranged in an alternating manner in the z-direction. The ILD layers 114 and the ESLs 116 may extend in the x-direction and/or in the y-direction in the semiconductor device 100.

The ILD layers 114 may each include a low dielectric constant (low-k) oxide material such as silicon oxide (SiOₓ) or undoped silicate glass (USG). Additionally and/or alternatively, the ILD layers 114 may each include a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 114 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (α-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples.

The ESLs 116 may each include a silicon nitride (SiₓN_{y}), silicon carbide (SiC), silicon oxynitride (SiON), and/or another suitable dielectric material. In some implementations, an ILD layer 114 and an ESL 116 include different dielectric materials to provide etch selectivity to enable various structures to be formed in the interconnect layer 104. For example, the ILD layers 114 may each include a low-k dielectric material such as USG, and the ESLs 116 may each include a high-k dielectric material such as silicon nitride (SiₓN_{y}) or silicon carbide (SiC). Additionally and/or alternatively, two or more ESLs 116 may include different materials. For example, one or more first ESLs 116 may include silicon nitride (SiₓN_{y}), and one or more second ESLs 116 may include silicon carbide (SiC).

The interconnect layer 104 includes a plurality of conductive structures that are arranged in a plurality of layers. The conductive structures may be electrically coupled and/or physically coupled with one or more of the integrated circuit devices 108 in the device layer 102. The conductive structures provide electrical routing that enables signals and/or power to be provided to and/or from the integrated circuit devices 108.

The layers of conductive structures may include a plurality of layers 118a-118e that are vertically arranged and alternate with a plurality of layers 120a-120d in the z-direction (e.g., vertically alternate). The layers 118a-118e each include a layer of metallization structures 122, and the layers 120a-120d each include a layer of interconnect structures 124.

The layers 118a-118e of metallization structures 122 may be referred to as M-layers. For example, a layer 118a of metallization structures 122 (referred to as a metal-0 (M0) layer) may be located at the bottom of the interconnect layer 104 and may be coupled with the device layer 102. In particular, the metallization structures 122 in the M0 layer may be coupled with the contacts 112 (e.g., a contact layer referred to as “CO”-layer) of the integrated circuit devices 108 in the device layer 102. A layer 118b of metallization structures 122 (referred to as a metal-1 layer (M1) layer) may be located above the layer 118a of metallization structures 122 in the interconnect layer 104, a layer 118c of metallization structures 122 (referred to as a metal-2 layer (M2) layer) may be located above the a layer 118b of metallization structures 122, and so on.

A layer 120a of interconnect structures 124 (referred to as a via-1 (V0) layer) may be included between the M0 layer and the M1 layer to interconnect the M0 layer and the M1 layer, a layer 120b of interconnect structures 124 (referred to as a via-2 (V1) layer) may be included between the M1 layer and the M2 layer to interconnect the M1 layer and the M2 layer, and so on.

The metallization structures 122 may include a combination of trenches, metallization layers, conductive traces, and/or other types of conductive structures. The interconnect structures 124 may include a combination of vias, interconnects, and/or other types of conductive structures. The metallization structures 122 and the interconnect structures 124 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the dielectric layers of the interconnect layer 104 and the metallization structures 122, and/or between the dielectric layers of the interconnect layer 104 the interconnect structures 124. The one or more liner layers may include barrier liners, adhesion liners, and/or another type of liners. Examples of materials for the one or more liners include tantalum nitride (TaN) and/or titanium nitride (TiN), among other examples.

In some implementations, the topmost layer of conductive structures (e.g., a topmost layer of metallization structures 122, a topmost layer of interconnect structures 124) may be coupled to connection structures at the top of the semiconductor device 100. The connection structures may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. In some implementations, the topmost layer of conductive structures (e.g., a topmost layer of metallization structures 122, a topmost layer of interconnect structures 124) may be coupled to bonding structures, such as bonding pads and/or bonding vias.

As further shown in FIG. 1A, a trench capacitor structure 126a is included in the interconnect layer 104 of the semiconductor device 100, and as further shown in FIG. 1B, a trench capacitor structure 126b is included in the interconnect layer 104 of the semiconductor device 100. The trench capacitor structures 126a and 126b may extend through and/or may be included in one or more dielectric layers in the interconnect layer 104, such as one or more ILD layers 114 and/or one or more ESLs 116. In some implementations, an integrated circuit device 108 is electrically coupled to a trench capacitor structure 126a or a trench capacitor structure 126b to form a memory cell (e.g., a dynamic random access memory (DRAM) cell or another type of capacitor-based memory cell) in the semiconductor device 100. In some implementations, a trench capacitor structure 126a or a trench capacitor structure 126b is configured to provide charge decoupling for one or more integrated circuit devices 108. In some implementations, a trench capacitor structure 126a or a trench capacitor structure 126b is configured to store a charge (e.g., a photocurrent) for an integrated circuit device 108 (e.g., a pixel sensor) in the semiconductor device 100. In some implementations, a trench capacitor structure 126a or a trench capacitor structure 126b is configured to perform another function in the semiconductor device 100.

The trench capacitor structure 126a and the trench capacitor structure 126b may be electrically coupled and/or physically coupled to a first bottom contact 128 and a second bottom contact 130 at a bottom of the trench capacitor structure 126a and the trench capacitor structure 126b. The first bottom contact 128 and the second bottom contact 130 may each include one or more conductive structures in the interconnect layer 104, such as one or more metallization structures 122 and/or one or more interconnect structures 124, among other examples. In some implementations, a trench capacitor structure may be electrically coupled and/or physically coupled to a top contact. For example, referring to FIG. 1B, the trench capacitor structure 126b is coupled to a metallization structure 122 (e.g., top contact) through an interconnect structure 124.

As indicated above, FIGS. 1A and 1B are provided as an example. Other examples may differ from what is described with regard to FIGS. 1A and 1B.

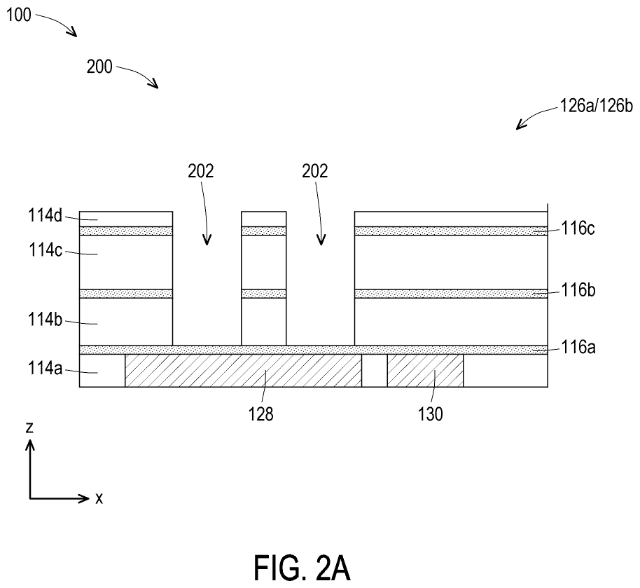

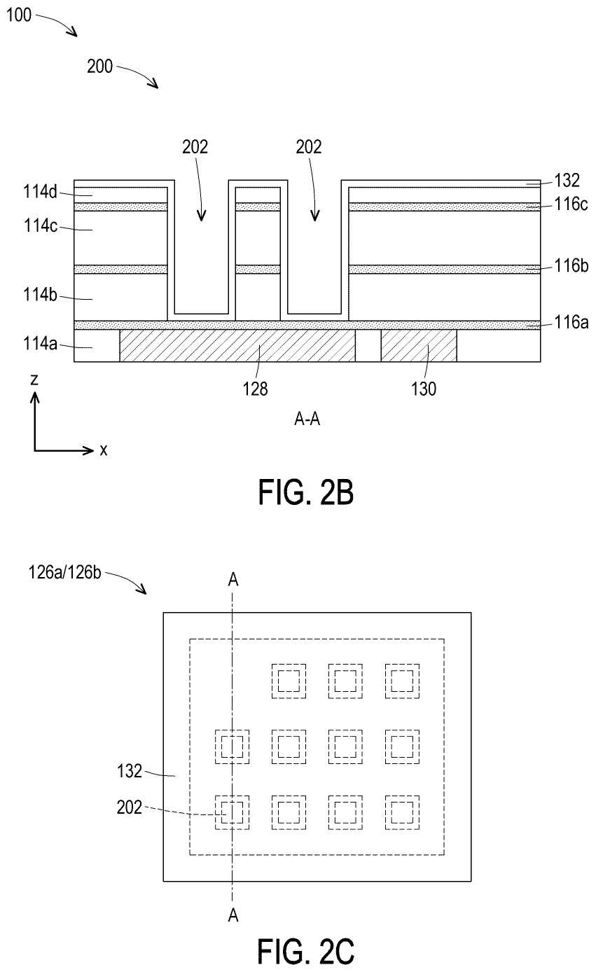

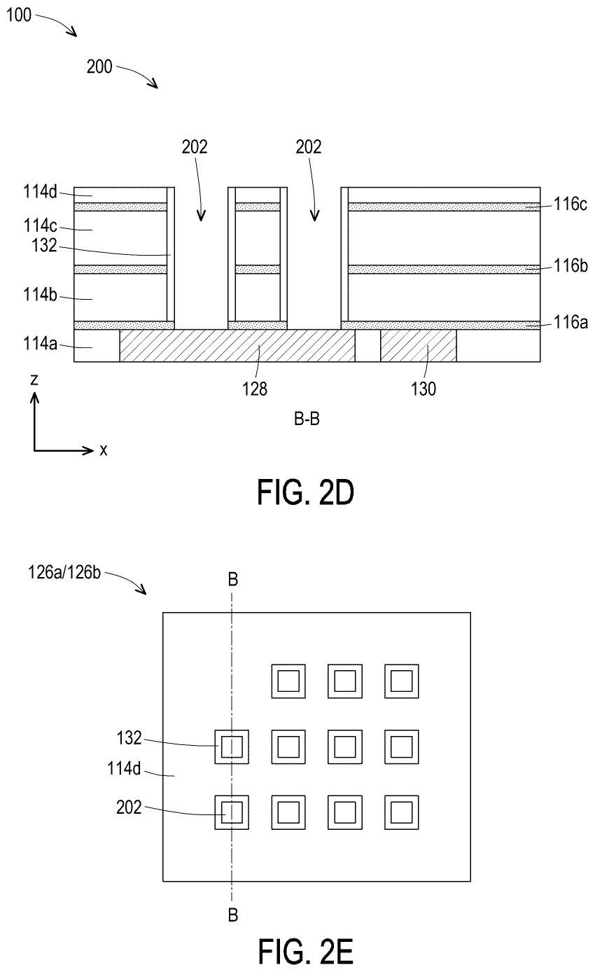

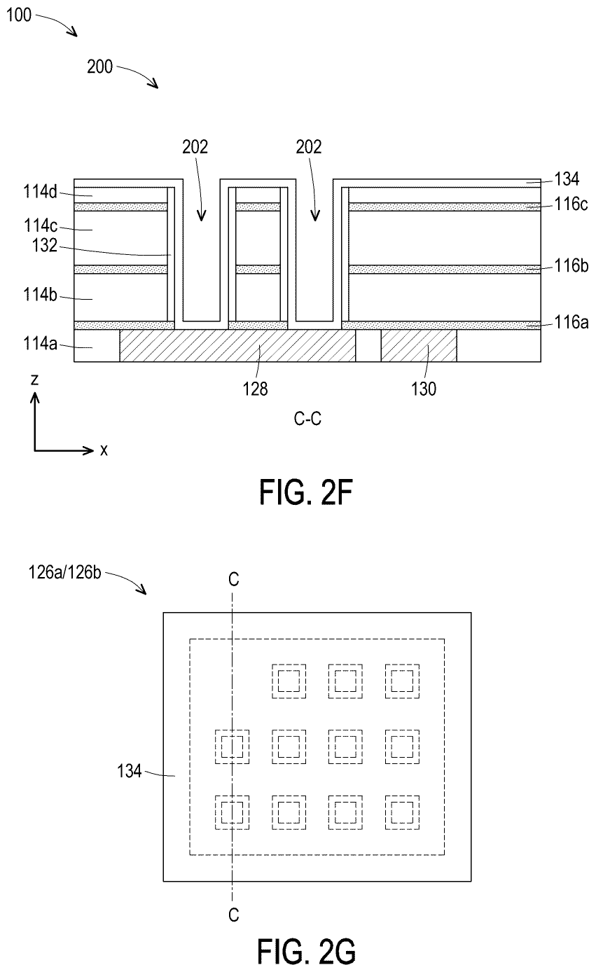

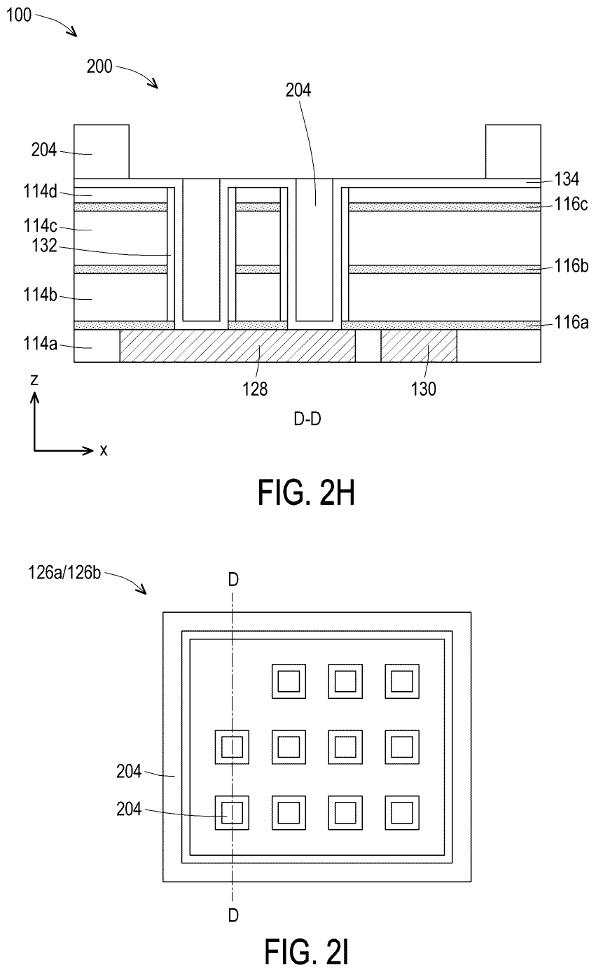

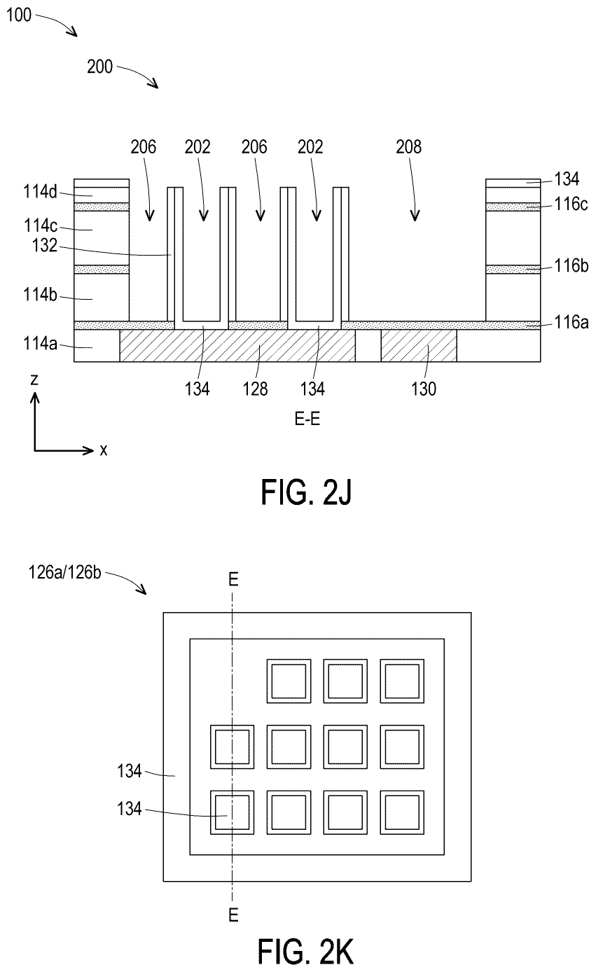

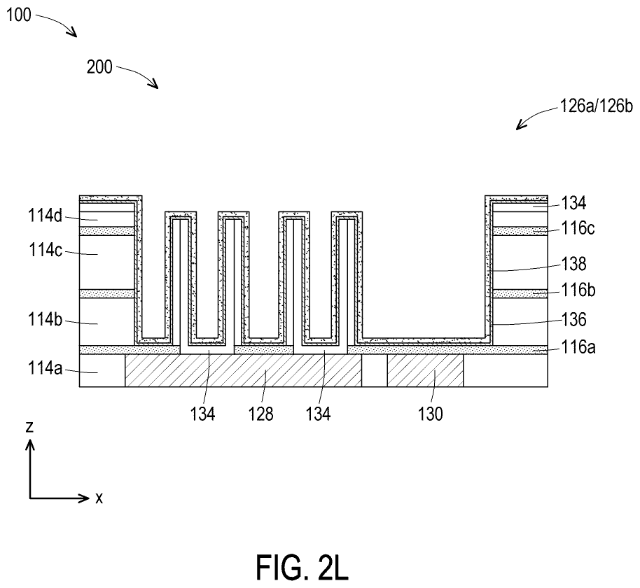

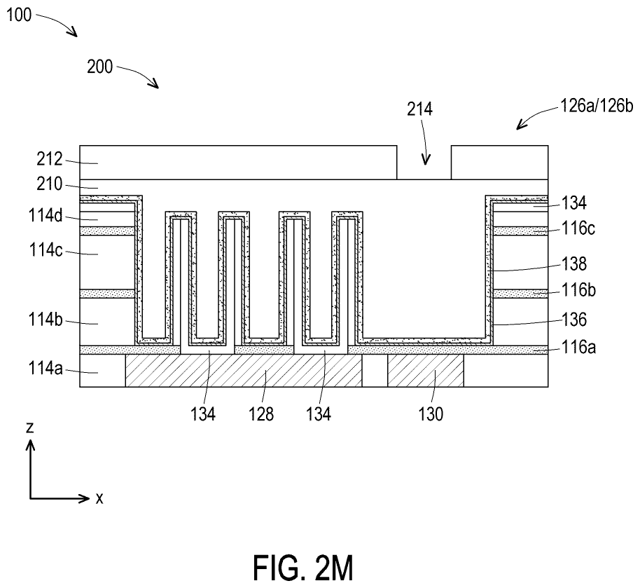

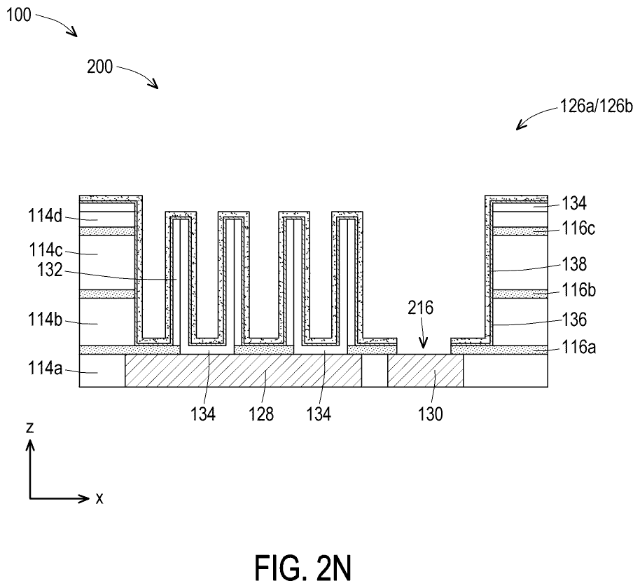

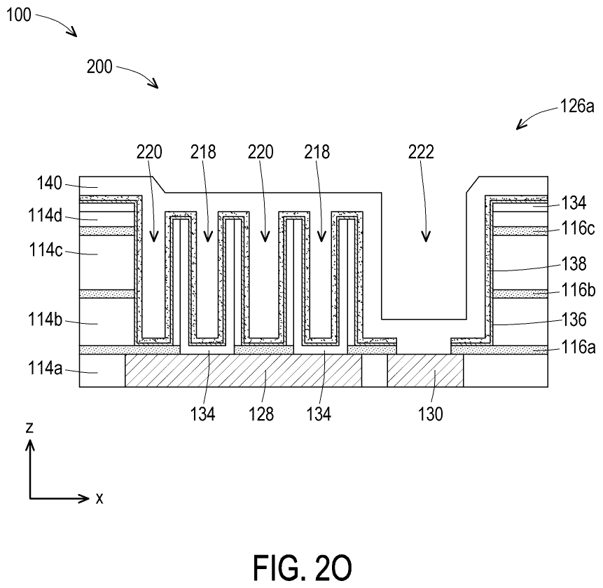

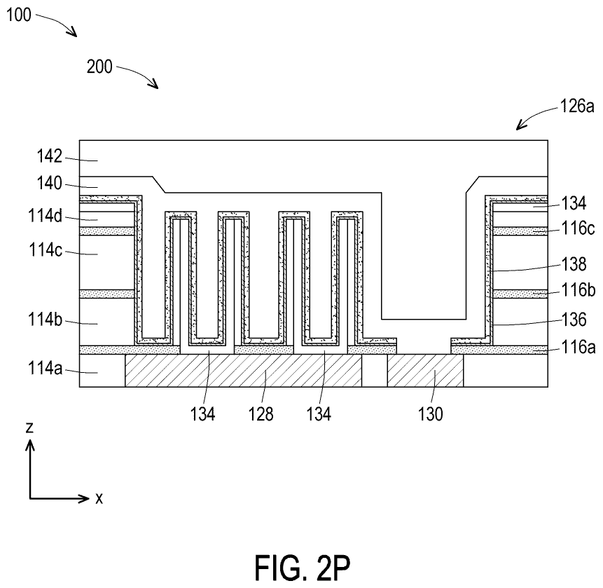

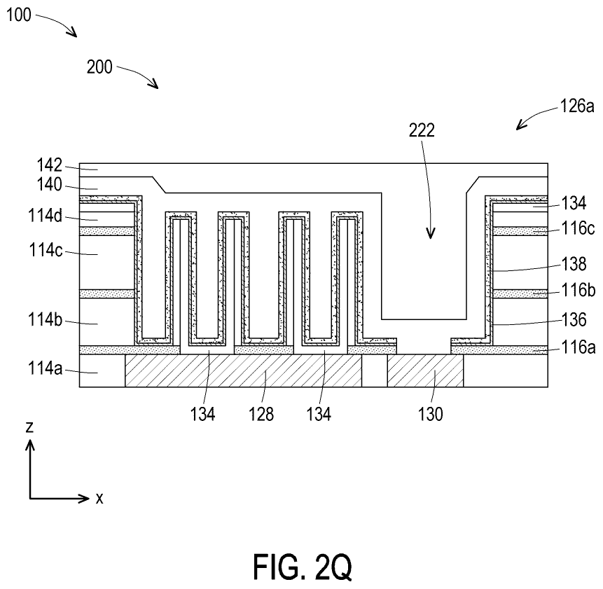

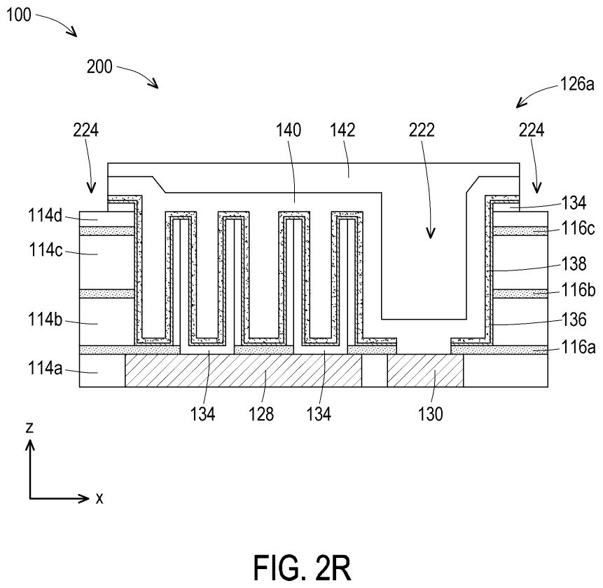

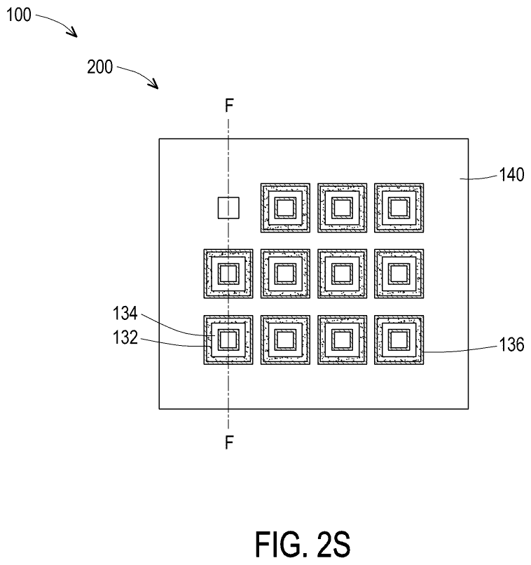

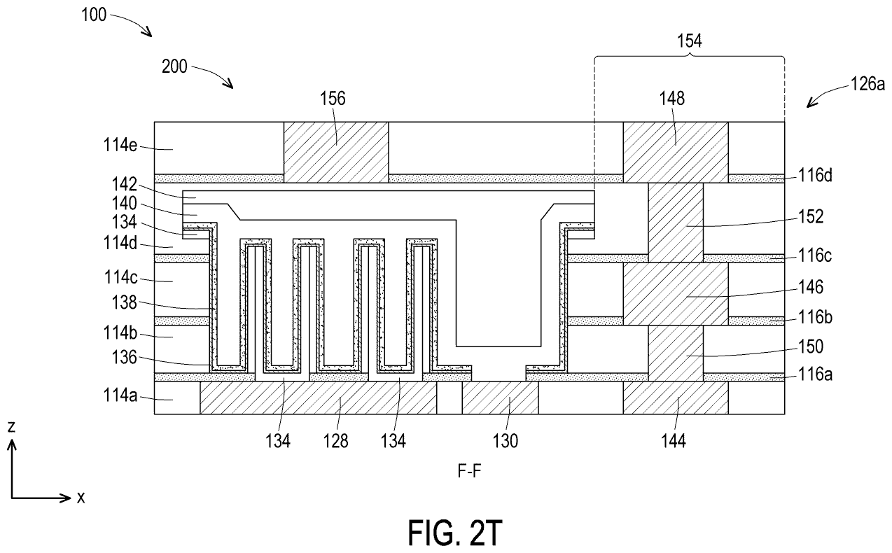

FIGS. 2A-2T are diagrams of an example implementation 200 of forming the semiconductor device 100 described herein. In some implementations, one or more of the semiconductor processing operations described in connection with FIGS. 2A-2T may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 2A, in connection with forming the trench capacitor structure 126a and the trench capacitor structure 126b, one or more trenches 202 are formed over the first bottom contact 128. The first bottom contact 128 and the second bottom contact 130 may be included in an ILD layer 114a in the interconnect layer 104 of the semiconductor device 100, and top surfaces of the first bottom contact 128 and the second bottom contact 130 may be coplanar or substantially coplanar with each other. Initially, a trench 202 of the trench capacitor structure 126a and the trench capacitor structure 126b may extend through one or more dielectric layers in the interconnect layer 104 of the semiconductor device 100, including through an ILD layer 114b, an ESL 116b, an ILD layer 114c, an ESL 116c, and/or an ILD layer 114d, among other examples. In some implementations, the trench(es) 202 may have a high aspect ratio, which is a ratio of a depth (or height) of the trench(es) 202 to a lateral width (or critical dimension) of the trench(es) 202. Thus, the trench capacitor structure 126a and the trench capacitor structure 126b may be referred to as a deep trench capacitor (DTC) structure. In some implementations, the aspect ratio of a trench 202 may be approximately 10:1 or greater. In some implementations, a trench 202 may have an aspect ratio that is included in the range of approximately 20:1 to approximately 50:1. However, other values and ranges are within the scope of the present disclosure.

FIG. 2B is a cross section of the line A-A in the top view of FIG. 2C. As shown in FIGS. 2B and 2C, a protective conductive layer 132 may be deposited on the sidewalls and on the bottom surfaces of the trench(es) 202. The bottom surfaces of the trench(es) 202 correspond to the top surface of the ESL 116a, and thus the protective conductive layer 132 may be in physical contact with the top surface of the ESL 116a. The protective conductive layer 132 may also be deposited on the top surface of the ILD layer 114d between and/or next to adjacent trenches 202 such that the protective conductive layer 132 may be in physical contact with the top surface of the ILD layer 114d. In some implementations, a deposition tool is used to conformally deposit the protective conductive layer 132 such that the protective conductive layer 132 conforms to the profile of the trench(es) 202. In some implementations, a conformal chemical vapor deposition (CVD) technique and/or an atomic layer deposition (ALD) technique is used to deposit the protective conductive layer 132. Examples of materials for the protective conductive layer 132 include tantalum nitride (TaN), titanium nitride (TiN), aluminum (Al), and/or tungsten (W), among other examples. As shown in FIG. 2C, an array of trenches 202 may be included in the semiconductor device 100.

FIG. 2D is a cross section of the line B-B in the top view of FIG. 2E. As shown in FIGS. 2D and 2E, horizontal portions (extending in the x-direction) of the protective conductive layer 132 are removed from the trench(es) 202 and from the top surface of the ILD layer 114d using a directional reactive ion etch (RIE) process, where gas etchants such as, for example, oxygen (O2), argon (Ar) and/or fluorine-based gases can be used. The fluorine-based etchants may include a carbon-fluoride-based (CFₓ) gas etchant such as a carbon tetrafluoride (CF₄) gas etchant. As can be seen in FIG. 2D, the reactive ion etch (RIE) process also removes portions of the ESL 116a to deepen the trench(es) 202, such that the trench(es) 202 expose portions of the top surface of the first bottom contact 128. Remaining portions of the protective conductive layer 132 are on part of the top surface of remaining portions of the ESL 116a.

FIG. 2F is a cross section of the line C-C in the top view of FIG. 2G. As shown in FIGS. 2F and 2G, a bottom electrode layer 134 may be deposited on the sidewalls and on the bottom surfaces of the trench(es) 202. The bottom surfaces of the trench(es) 202 correspond to the top surface of the first bottom contact 128, and thus the bottom electrode layer 134 may be in physical contact with the top surface of the first bottom contact 128. The sidewalls of the trench(es) 202 correspond to side surfaces of protective conductive layers 132, and thus the bottom electrode layer 134 may be in physical contact with the side surfaces of the protective conductive layers 132. The bottom electrode layer 134 may also be deposited on the top surface of the ILD layer 114d and top surfaces of the protective conductive layers 132 between and/or next to adjacent trenches 202, such that the bottom electrode layer 134 may be in physical contact with the top surfaces of the ILD layer 114d and the protective conductive layers 132. In some implementations, a deposition tool is used to conformally deposit the bottom electrode layer 134 such that the bottom electrode layer 134 conforms to the profile of the trench(es) 202.

In some implementations, a conformal CVD technique and/or an ALD technique is used to deposit the bottom electrode layer 134.

In some implementations, a barrier layer may be deposited on the sidewalls and on the bottom surfaces of the trench(es) 202 prior to depositing the bottom electrode layer 134. In this case, the barrier layer may be in physical contact with the top surface of the first bottom contact 128, and in physical contact with the side surfaces of the protective conductive layers 132. The barrier layer may also be deposited on the top surface of the ILD layer 114d and top surfaces of the protective conductive layers 132 between and/or next to adjacent trenches 202, such that the barrier layer may be in physical contact with the top surfaces of the ILD layer 114d and the protective conductive layers 132. In some implementations, a deposition tool is used to conformally deposit the barrier layer such that the barrier layer conforms to the profile of the trench(es) 202. In some implementations, a conformal CVD technique and/or an ALD technique is used to deposit the barrier layer. The barrier layer prevents upward migration of an electrically conductive material (e.g., copper (Cu)) of the first bottom contact 128 into the bottom electrode layer 134, and may include tantalum (Ta), tantalum nitride (TaN), and/or another suitable barrier material. With or without the barrier layer, the bottom electrode layer 134 is electrically connected to the first bottom contact 128.

FIG. 2H is a cross section of the line D-D in the top view of FIG. 2I. As shown in FIGS. 2H and 2I, a photoresist layer 204 is deposited in the trench(es) 202 and on the top surface of the bottom electrode layer 134. In some implementations, a deposition tool may be used to form the photoresist layer 204 in the trench(es) 202 and on the top surface of the bottom electrode layer 134. An exposure tool may be used to expose the photoresist layer 204 to a radiation source to pattern the photoresist layer 204. A developer tool may be used to develop and remove portions of the photoresist layer 204 to expose the pattern as shown in FIG. 2H.

FIG. 2J is a cross section of the line E-E in the top view of FIG. 2K. As shown in FIGS. 2J and 2K, the pattern in the photoresist layer 204 is used to etch exposed portions of the bottom electrode layer 134 and underlying portions of the ILD layers 114b, 114c, and 114d, and ESLs 116b and 116c to form additional trenches 206 and 208. An etch tool may be used to etch the exposed portions of the bottom electrode layer 134 and underlying portions of the ILD layers 114b, 114c, and 114d, and ESLs 116b and 116c based on the pattern to form the additional trenches 206 and 208. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer 204 (e.g., using a chemical stripper, plasma ashing, and/or another technique). In some implementations, a hard mask layer is used as an alternative technique for etching the exposed portions of the bottom electrode layer 134 and underlying portions of the ILD layers 114b, 114c, and 114d, and ESLs 116b and 116c based on a pattern to form the additional trenches 206 and 208.

Following the etch operation and removal of the remaining portions of the photoresist layer 204, portions of the bottom electrode layer 134 remain in the trench(es) 202 and on parts of a top surface of the ILD layer 114d. In addition, the protective conductive layers 132 remain on opposite side surfaces of the remaining portions of the bottom electrode layer 134 in the trench(es) 202. The remaining portions of the protective conductive layer 132 support the portions of the bottom electrode layer 134 in the trench(es) 202 to prevent collapse of the portions of the bottom electrode layer 134 in the trench(es) 202 after the etch operation and removal of the remaining portions of the photoresist layer 204. The remaining portions of the protective conductive layer 132 also protect (e.g., cover) the sidewalls of the bottom electrode layer 134 during the etch operation and any subsequent cleaning steps. For example, a wet clean operation to remove an etching polymer used during the etch operation from remaining un-etched surfaces may damage exposed portions of the bottom electrode layer 134. The protective conductive layer 134 prevents exposure of the bottom electrode layer 134 to chemicals used during the wet clean operation.

In some implementations, a thickness of the remaining portions of the protective conductive layer 132 may be included in the range of approximately 100 angstroms to approximately 1000 angstroms. However, other values and ranges are within the scope of the present disclosure. A thickness of the remaining portions of the protective conductive layer 132 that is less than approximately 100 angstroms may result in a lack of support and/or a lack of protection from wet clean chemicals for the remaining portions of the bottom electrode layer 134 in the trench(es) 202. A thickness of the remaining portions of the protective conductive layer 132 that is greater than approximately 1000 angstroms may result in difficulty (e.g., a lack of adequate space) forming the remaining layers of the trench capacitor structure 126a and/or 126b in the additional trenches 206 and 208.

A trench 202, 206, and/or 208 of the trench capacitor structure 126a and/or 126b may extend through one or more dielectric layers in the interconnect layer 104 of the semiconductor device 100, including through an ESL 116a, an ILD layer 114a, an ESL 116b, an ILD layer 114c, an ESL 116c, and/or an ILD layer 114d, among other examples. In some implementations, trenches of the trench capacitor structure 126a and/or 126b may have a high aspect ratio, which is a ratio of a depth (or height) of the trenches to a lateral width (or critical dimension) of the trenches. Thus, the trench capacitor structure 126a and/or the trench capacitor structure 126b may be referred to as a DTC structure. In some implementations, the aspect ratio of a trench 202, 206, and/or 208 may be approximately 10:1 or greater. In some implementations, a trench 202, 206, and/or 208 may have an aspect ratio that is included in the range of approximately 20:1 to approximately 50:1. However, other values and ranges are within the scope of the present disclosure.

As shown in FIG. 2L, an insulator layer 136 may be deposited on the sidewalls and on the bottom surfaces of the trenches 206 and 208, and on exposed surfaces of the bottom electrode layer 134 in the trench(es) 202. The bottom surfaces of the trenches 206 and 208 correspond to the top surface of the ESL 116a, and thus the insulator layer 136 may be in physical contact with the top surface of the ESL 116a. Some or each of the sidewalls of the trenches 206 and 208 may correspond to side surfaces of protective conductive layers 132, and thus the insulator layer 136 may be in physical contact with the side surfaces of the protective conductive layers 132. The insulator layer 136 may also be deposited on the top surface of remaining portions of the bottom electrode layer 134 on the ILD layer 114d and on top surfaces of portions of the bottom electrode layer 134 and the protective conductive layers 132 between and/or next to adjacent trenches 202, 206, and 208, such that the insulator layer 136 may be in physical contact with the top surfaces of the bottom electrode layer 134 and the protective conductive layers 132. In some implementations, a deposition tool is used to conformally deposit the insulator layer 136 such that the insulator layer 136 conforms to the profiles of the trenches 202, 206, and 208. In some implementations, a conformal CVD technique and/or an ALD technique is used to deposit the insulator layer 136.

The insulator layer 136 may include one or more electrically insulating materials. In some implementations, the insulator layer 136 includes one or more low-k dielectric materials such as silicon oxide (SiOₓ such as SiO₂). Additionally and/or alternatively, the insulator layer 136 may include one or more high-k dielectric materials such as zirconium oxide (ZrOₓ such as ZrO₂), aluminum oxide (AlₓO_{y} such as Al₂O₃), silicon nitride (SiₓN_{y} such as Si₃N₄), yttrium oxide (YₓO_{y} such as Y₂O₃), lanthanum oxide (LaₓO_{y} such as La₂O₃), and/or hafnium oxide (HfOₓ such as HfO₂), among other examples. In some implementations, the insulator layer 136 is a multiple-layer stack that includes a plurality of dielectric layers. For example, the insulator layer 136 may include a ZrO₂/Al₂O₃/ZrO₂ (ZAZ) layer stack.

As further shown in FIG. 2L, a conductive layer 138 may be deposited on exposed surfaces of the insulator layer 136 in the trenches 202, 206, and 208. The conductive layer 138 may also be deposited on the top surface of the insulator layer 136 on the ILD layer 114d and on top surfaces of insulator layer 136 between and/or next to adjacent trenches 202, 206, and 208. In some implementations, a deposition tool is used to conformally deposit the conductive layer 138 such that the conductive layer 138 conforms to the profile of the trenches 202, 206, and 208.

In some implementations, a conformal CVD technique and/or an ALD technique is used to deposit the conductive layer 138. The conductive layer 138 may include titanium nitride (TiN), and/or another suitable conductive material.

As shown in FIG. 2M, a bottom antireflective coating (BARC) layer 210 is deposited in the trenches 202, 206, and 208, and then a photoresist layer 212 is deposited onto the BARC layer 210. A pattern 214 may be formed in the photoresist layer 212. A deposition tool may be used to deposit the BARC layer 210 in the trenches 202, 206, and 208, and to form the photoresist layer 212 on the BARC layer 210 (e.g., using a spin-coating technique or another suitable deposition technique). An exposure tool may be used to expose the photoresist layer 212 to a radiation source to pattern the photoresist layer 212. A developer tool may be used to develop and remove portions of the photoresist layer 212 to expose the pattern 214.

As shown in FIG. 2N, an etch tool may be used to etch the BARC layer 210 and underlying portions of the insulator layer 136 and of the conductive layer 138 based on the pattern 214 in the photoresist layer 212, to create an opening 216 exposing a portion of the top surface of the second bottom contact 130. In some implementations, the etch operation includes a dry etch operation (e.g., a plasma-based etch operation, a gas-based etch operation), a wet chemical etch operation, and/or another type of etch operation. Gas etchants such as, for example, oxygen (O₂), argon (Ar) and/or fluorine-based gases can be used. The fluorine-based etchants may include a carbon-fluoride-based (CFₓ) gas etchant such as a carbon tetrafluoride (CF₄) gas etchant. In some implementations, a photoresist removal tool may be used to remove the remaining portions of the photoresist layer (e.g., using a chemical stripper, plasma ashing, and/or another technique).

As shown in FIG. 2O, a top electrode layer 140 may be deposited on exposed surfaces of the conductive layer 138 in the trenches 202, 206, and 208, and on the exposed portion of the top surface of the second bottom contact 130 in the trench 208. The top electrode layer 140, a portion of which is formed over the second bottom contact 130, may be in physical contact with the second bottom contact 130. As a result of the deposition of the top electrode layer 140, trench structures 218, 220, and 222, respectively corresponding to the trenches 202, 206, and 208, are formed. Each of the trench structures 218, 220, and 222 includes a plurality of conformal layers that conform to the profile of the trenches 202, 206, and 208. In the trench structures 218, the conformal layers may include a bottom electrode layer 134, an insulator layer 136 on the bottom electrode layer 134, and a conductive layer 138 on the insulator layer 136. In the trench structures 220 and 222, the conformal layers may include an insulator layer 136, and a conductive layer 138 on the insulator layer 136. The trench structures 220 and 222 do not include the bottom electrode layer 134. The bottom electrode layer 134, the insulator layer 136, and the conductive layer 138 may each conform to the profile of the trench(es) 202 such that the bottom electrode layer 134, the insulator layer 136, and the conductive layer 138 conform to (e.g., are disposed along) the sidewalls and the bottom surfaces of the trench(es) 202. With the exception of the exposed top surface of the second bottom contact in the trench 208, the insulator layer 136 and the conductive layer 138 may each conform to the profile of the trenches 206 and 208 such that the insulator layer 136 and the conductive layer 138 conform to (e.g., are disposed along) the sidewalls and the bottom surfaces of the trenches 206 and 208. The trench capacitor structure 126a further includes the top electrode layer 140 on the conductive layer 138, and on the exposed portion of the top surface of the second bottom contact 130. In some implementations, the top electrode layer 140 is a fill layer that fills in the remaining areas of the trenches 202 and 206.

As shown in FIG. 2P, in the trench 208, the top electrode layer 140 is a conformal layer that conforms to the sidewalls and the bottom surfaces of the trench 208, and a dielectric plug layer 142 is further included in the remaining areas of the trench 208. The dielectric plug layer 142 may be, for example, an oxide (e.g., a silicon oxide (SiOₓ) and/or another oxide material), and/or another type of dielectric material. A deposition tool may be used to deposit the dielectric plug layer 142 on the top electrode layer 140 using a physical vapor deposition (PVD) technique, an atomic layer deposition (ALD) technique, a chemical vapor deposition (CVD) technique, an oxidation technique, and/or another suitable deposition technique.

As shown in FIG. 2Q, in some implementations, a planarization tool may be used to perform a planarization operation such as a chemical mechanical planarization (CMP) operation to planarize the dielectric plug layer 142 after the dielectric plug layer 142 is deposited. Alternatively, a blanket etch operation may be performed to reduce a thickness of the dielectric plug layer 142 in the z-direction.

The bottom electrode layer 134, the insulator layer 136, and the top electrode layer 140 correspond to an MIM structure of the trench capacitor structure 126a. Thus, the trench capacitor structure 126a may also be referred to as an MIM capacitor structure. The bottom electrode layer 134 (also referred to as a capacitor bottom metal (CBM)) and the top electrode layer 140 (also referred to as a capacitor top metal (CTM)) may each include one or more electrically conductive metals, one or more electrically conductive metal-containing materials, one or more electrically conductive ceramic materials, and/or other types of electrically conductive materials. Examples include tungsten (W), cobalt (Co), ruthenium (Ru), titanium (Ti), aluminum (Al), copper (Cu), gold (Au), titanium nitride (TiN), and/or tantalum nitride (TaN), among other examples. In some implementations, the bottom electrode layer 134 and the top electrode layer 140 include the same material or the same material composition. In some implementations, the bottom electrode layer 134 and the top electrode layer 140 include different materials or different material compositions.

In some implementations, a barrier layer may be deposited on the exposed surfaces of the conductive layer 138 in the trenches 202, 206, and 208, and on the exposed portion of the top surface of the second bottom contact 130 in the trench 208 prior to depositing the top electrode layer 140. In this case, the barrier layer may be in physical contact with the top surface of the second bottom contact 130. In some implementations, a deposition tool is used to conformally deposit the barrier layer such that the barrier layer conforms to the profile of the trenches 202, 206, and 208. In some implementations, a conformal CVD technique and/or an ALD technique is used to deposit the barrier layer. The barrier layer prevents upward migration of an electrically conductive material (e.g., copper (Cu)) of the second bottom contact 130 into the top electrode layer 140, and may include tantalum (Ta), tantalum nitride (TaN), and/or another suitable barrier material. With or without the barrier layer, the top electrode layer 140 is electrically connected to the second bottom contact 130.

FIG. 2R is a cross section of the line F-F in the top view of FIG. 2S. As shown in FIGS. 2R and 2S, side portions of the dielectric plug layer 142, the top electrode layer 140, the conductive layer 138, the insulator layer 136, the bottom electrode layer 134 and the ILD layer 114d are removed to result in the patterned trench capacitor structure 126a. The removal results in step portions 224 where the side portions of the dielectric plug layer 142, the top electrode layer 140, the conductive layer 138, the insulator layer 136, the bottom electrode layer 134 and the ILD layer 114d were removed. In some implementations, a mask layer is formed on part of the dielectric plug layer 142, and an etch operation is performed to etch portions not covered by the mask layer. The etch operation may include a dry etch operation (e.g., a plasma-based etch operation, a gas-based etch operation), a wet chemical etch operation, and/or another type of etch operation. Gas etchants such as, for example, oxygen (O₂), argon (Ar) and/or fluorine-based gases can be used. The fluorine-based etchants may include a carbon fluoride-based (CFₓ) gas etchant such as a carbon tetrafluoride (CF₄) gas etchant.

As shown in FIG. 2T, metallization structures 144, 146, and 148, and interconnect structures (e.g., vias) 150 and 152 are formed in a peripheral area 154 laterally adjacent to the trench capacitor structure 126a in the x-direction, and a metallization structure 156 is formed over the trench capacitor structure 126a in the z-direction. One or more deposition tools are used to deposit an additional portion of the ILD layer 114d to increase a vertical height of the ILD layer 114d in the z-direction, and to deposit ESL 116d and ILD layer 114e. In this way, the ILD layers 114 and ESLs 116 may be arranged in the z-direction in the semiconductor device 100. One or more deposition tools may be used to deposit each of the ILD layers 114 and each of the ESLs 116 using a PVD technique, an ALD technique, a CVD technique, an oxidation technique, and/or another suitable deposition technique. In some implementations, a planarization tool may be used to planarize the ILD layers 114 and/or the ESLs 116 after the ILD layers 114 and/or the ESLs 116 are deposited.

As further shown in FIG. 2T, a deposition tool, an exposure tool, a developer tool, an etch tool, a planarization tool, a plating tool, and/or another semiconductor processing tool may be used to perform various operations to form the metallization structures 144, 146, 148, and 156, and to form the interconnect structures 150 and 152. In some implementations, the first bottom contact 128, the second bottom contact, the metallization structures 144, 146, 148, and 156, and the interconnect structures 150 and 152 may be formed in a plurality of layers. For example, an ILD layer 114 and an ESL 116 may be formed (e.g., using one or more deposition tools and/or one or more planarization tools), recesses may be formed in and/or through the ILD layer 114 and the ESL 116 (e.g., using an exposure tool, a developer tool, and/or an etch tool), and the layer (e.g., the M0 layer) including the first bottom contact 128, the second bottom contact, and the metallization structure 144 may be formed in the ILD layer 114a and the ESL 116a (e.g., using one or more deposition tools and/or one or more planarization tools). Another ILD layer 114b and another ESL 116b may be formed, and the layer (e.g., the V0 layer) including interconnect structure 150 may be formed in the ILD layer 114b and the ESL 116b.

The remaining layers may be formed in a similar manner.

One or more deposition tools may be used to deposit the metallization structures 144, 146, 148, and 156, the interconnect structures 150 and 152, the first bottom contact 128, and/or the second bottom contact 130 using a PVD technique, an ALD technique, a CVD technique, an electroplating technique (e.g., an electro-chemical plating technique), and/or another suitable deposition technique. In some implementations, a planarization tool may be used to planarize the metallization structures 144, 146, 148, and 156, the interconnect structures 150 and 152, the first bottom contact 128, and/or the second bottom contact 130 after the metallization structures 144, 146, 148, and 156, the interconnect structures 150 and 152, the first bottom contact 128, and/or the second bottom contact 130 are deposited.

As indicated above, FIGS. 2A-2T are provided as an example. Other examples may differ from what is described with regard to FIGS. 2A-2T.

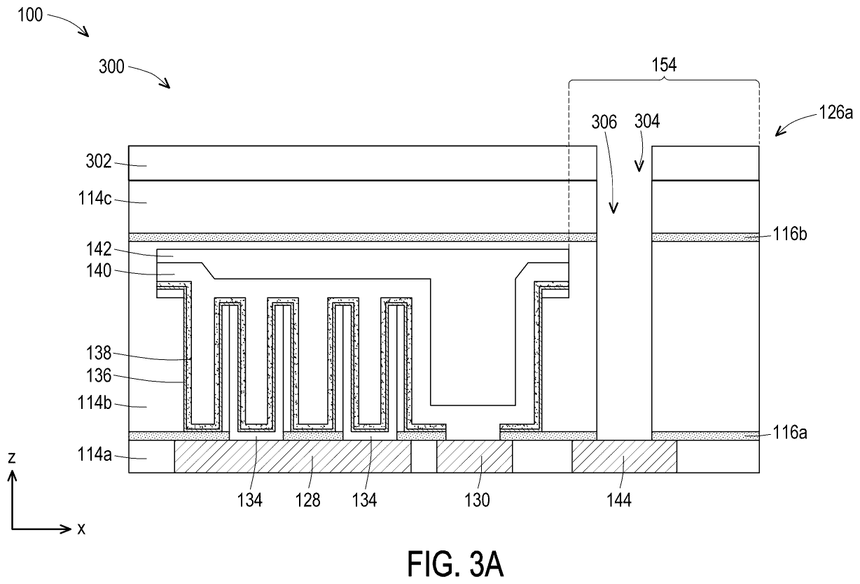

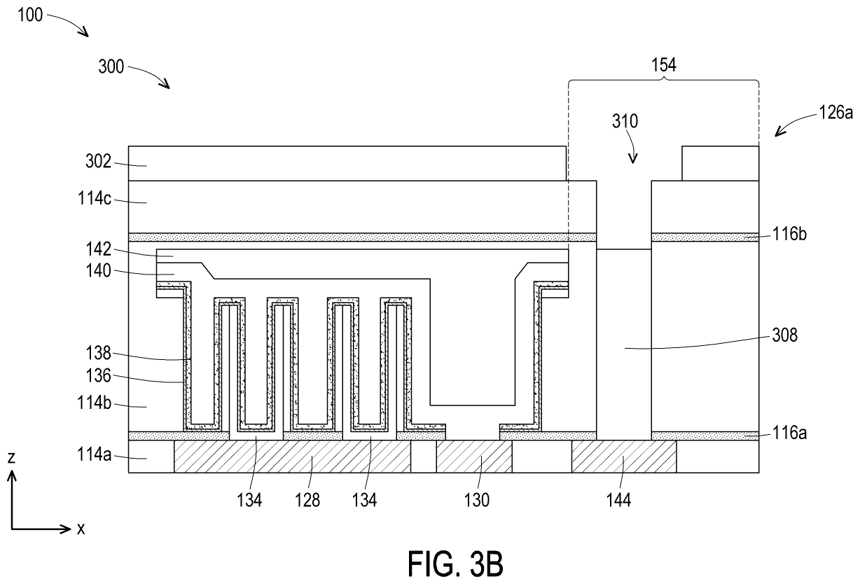

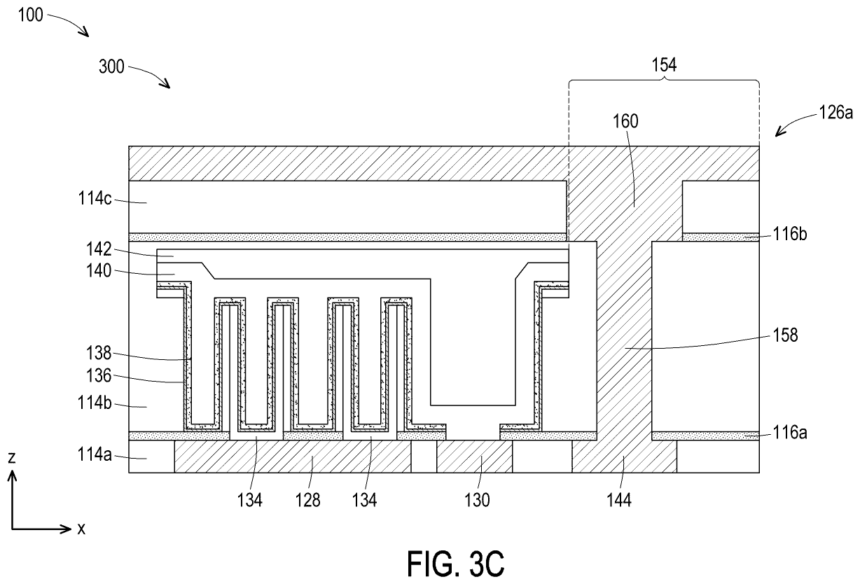

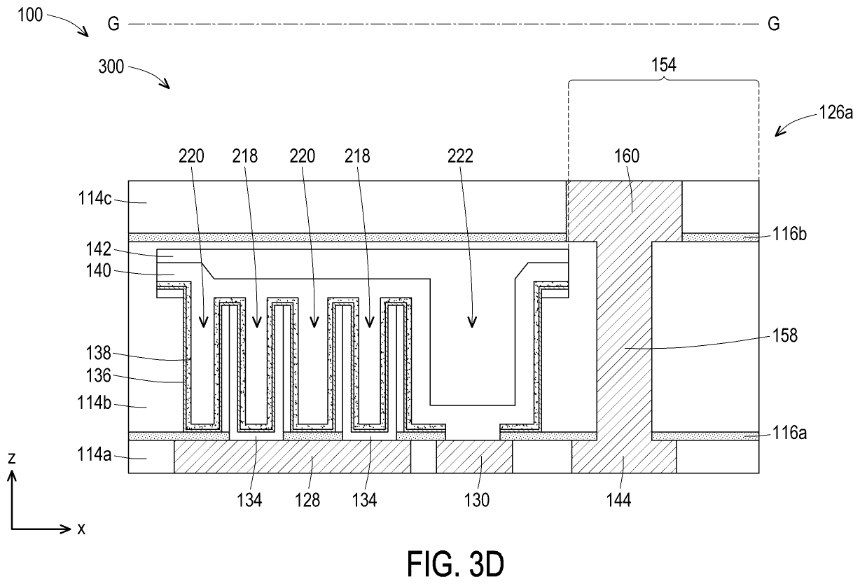

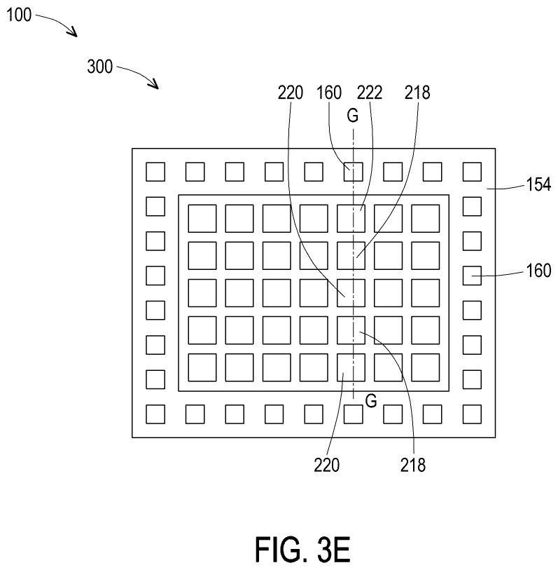

FIGS. 3A-3E are diagrams of an example implementation 300 of forming the semiconductor device 100 described herein. In some implementations, one or more of the semiconductor processing operations described in connection with FIGS. 3A-3E may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 3A, as an alternative to the example implementation 200 described in connection with FIGS. 2A-2T, the trench capacitor structure 126a in the example implementation 300 is formed in a continuous ILD layer 114b without the alternating arrangement of ILD layers 114b, 114c, and 114d, and ESLs 116b and 116c as shown in FIGS. 2A-2T. In other respects, the processing to form the trench capacitor structure 126a on the first bottom contact 128 and the second bottom contact 130 as shown in FIG. 3A, is the same or substantially the same as what is shown in FIGS. 2A-2R.

As shown in FIG. 3A, one or more deposition tools are used to deposit an additional portion of the ILD layer 114b to increase a vertical height of the ILD layer 114b in the z-direction, and to deposit ESL 116b and ILD layer 114c. In this way, the ILD layers 114 and ESLs 116 may be arranged in the z-direction in the semiconductor device 100. One or more deposition tools may be used to deposit each of the ILD layers 114 and each of the ESLs 116 using a PVD technique, an ALD technique, a CVD technique, an oxidation technique, and/or another suitable deposition technique. In some implementations, a planarization tool may be used to planarize the ILD layers 114 and/or the ESLs 116 after the ILD layers 114 and/or the ESLs 116 are deposited.

As further shown in FIG. 3A, a photoresist layer 302 is deposited on the top surface of the ILD layer 114c. In some implementations, a deposition tool may be used to form the photoresist layer 302 on the top surface of the ILD layer 114c. An exposure tool may be used to expose the photoresist layer 302 to a radiation source to pattern the photoresist layer 302. A developer tool may be used to develop and remove portions of the photoresist layer 302 to expose the pattern 304 as shown in FIG. 3A. The pattern 304 in the photoresist layer 302 is used to etch an exposed portion of the ILD layer 114c and underlying portions of the ILD layer 114b and ESLs 116a and 116b to form an opening 306 exposing a top surface of the metallization structure 144 in the peripheral area 154. An etch tool may be used to etch the exposed portion of the ILD layer 114c and underlying portions of the ILD layer 114b and ESLs 116a and 116b based on the pattern to form the opening 306. In some implementations, the etch operation includes a dry etch operation (e.g., a plasma-based etch operation, a gas-based etch operation), a wet chemical etch operation, and/or another type of etch operation. In some implementations, a hard mask layer is used as an alternative technique for etching the exposed portion of the ILD layer 114c and underlying portions of the ILD layer 114b and ESLs 116a and 116b based on a pattern to form the opening 306.

As shown in FIG. 3B, a photoresist plug layer 308 is deposited in a portion of the opening 306 up to a height in the z-direction below the ESL 116b. In some implementations, a deposition tool may be used to form the photoresist plug layer 308 in the opening 306. An exposure tool may be used to further expose the photoresist layer 302 to a radiation source to widen the pattern 304 in the x-direction to form a wider pattern 310 in the photoresist layer 302. A developer tool may be used to develop and remove additional portions of the photoresist layer 302 to expose the wider pattern 310 as shown in FIG. 3B. The wider pattern 310 in the photoresist layer 302 is used to etch an exposed portion of the ILD layer 114c and underlying portions of the ILD layer 114b and ESL 116b to widen an upper portion of the opening 306 down to the top surface of the photoresist plug layer 308. An etch tool may be used to etch the exposed portion of the ILD layer 114c and underlying portions of the ILD layer 114b and ESL 116b based on the wider pattern 310 to widen the upper portion of the opening 306. In some implementations, the etch operation includes a dry etch operation (e.g., a plasma-based etch operation, a gas-based etch operation), a wet chemical etch operation, and/or another type of etch operation. In some implementations, a hard mask layer is used as an alternative technique for etching the exposed portion of the ILD layer 114c and underlying portions of the ILD layer 114b and ESL 116b based on a pattern to widen the upper portion of the opening 306. In some implementations, a photoresist removal tool may be used to remove the remaining portions of the photoresist layer 302 and the photoresist plug layer 308 (e.g., using a chemical stripper, plasma ashing, and/or another technique).

As shown in FIG. 3C, following removal of the remaining portions of the photoresist layer 302 and the photoresist plug layer 308, one or more deposition tools may be used to deposit a deep interconnect structure (e.g., deep via) 158 in the opening 306 on the metallization structure 144, and to deposit a metallization structure 160 in the widened upper portion of the opening 306 on the deep interconnect structure 158. As can be seen in FIG. 3C, part of the deposited metallization structure 160 is formed on the top surface of the ILD layer 114c. The deep interconnect structure 158 and the metallization structure 160 are deposited using a PVD technique, an ALD technique, a CVD technique, an electroplating technique (e.g., an electro-chemical plating technique), and/or another suitable deposition technique. As shown in FIG. 3D, which is a cross section of the line G-G in the top view of FIG. 3E, following the deposition of the metallization structure 160, a planarization tool may be used to planarize the metallization structure 160 to remove excess portions of the metallization structure 160 from the top surface of the ILD layer 114c. The deep interconnect structure 158 formed through the continuous ILD layer 114b in the example implementation 300 simplifies interconnect and metallization structure formation in the peripheral area 154, in comparison to the example implementation 200. For example, the deep interconnect structure 158 of the example implementation 300 replaces the metallization structure 146 and the interconnect structures 150 and 152 of the example implementation 200, which simplifies processing by using less masks.

As shown in FIG. 3E, a plurality of metallization structures 160 (and underlying deep interconnect structures 158) may be formed in a peripheral area 154 of the semiconductor device 100. In addition, an array of trench capacitor structures 126a including a plurality of trench structures 218, 220, and 222 may be included in the semiconductor device 100.

The trench capacitor structure 126a of the example implementations 200 and 300 uses the second bottom contact 130 to connect the top electrode layer 140 (e.g., CTM layer) to a voltage source (e.g., reset voltage) instead of top vias and contacts formed above MIM capacitor structures. As a result, capacitor area can be increased in comparison to MIM capacitor structures that utilize a top via connection to a CTM layer. The elimination of the top via connection also prevents plasma charge damage to the CTM layer that may be caused during an etching process to form a via which lands on the CTM layer. The connection of the top electrode layer 140 to the second bottom contact 130 also facilitates implementation of a local reset for a capacitor structure, since the bottom connection can be part of an existing metallization loop or part of an added metallization layer to connect the capacitor structure to the reset voltage inside a pixel, so that the capacitor can be reset locally with a reduced RC time constant, resulting in faster capacitor reset speeds and increased frame rates in comparison to other capacitor structures.

As indicated above, FIGS. 3A-3E are provided as an example. Other examples may differ from what is described with regard to FIGS. 3A-3E.

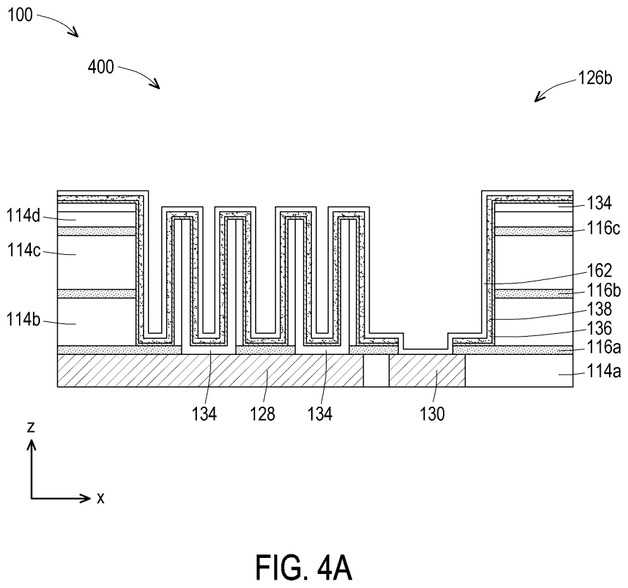

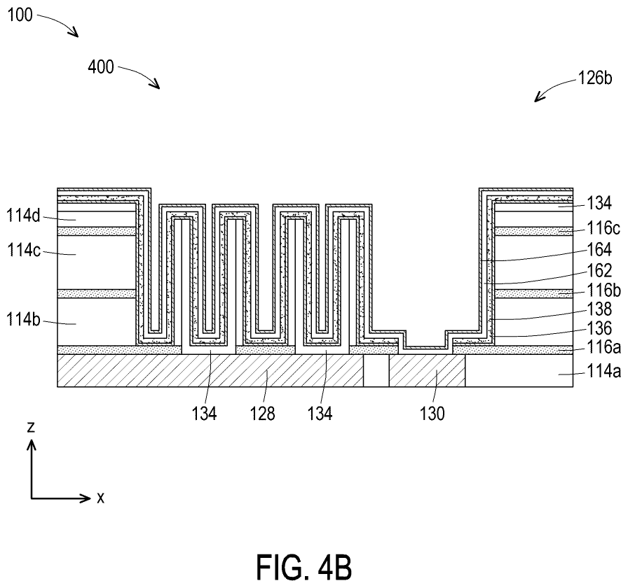

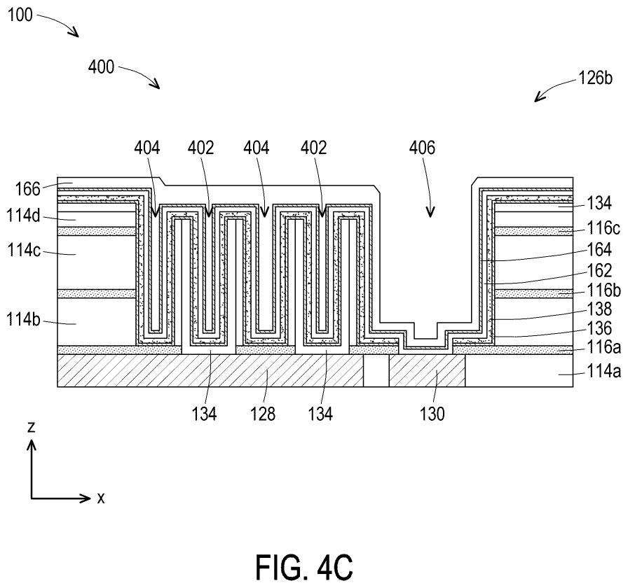

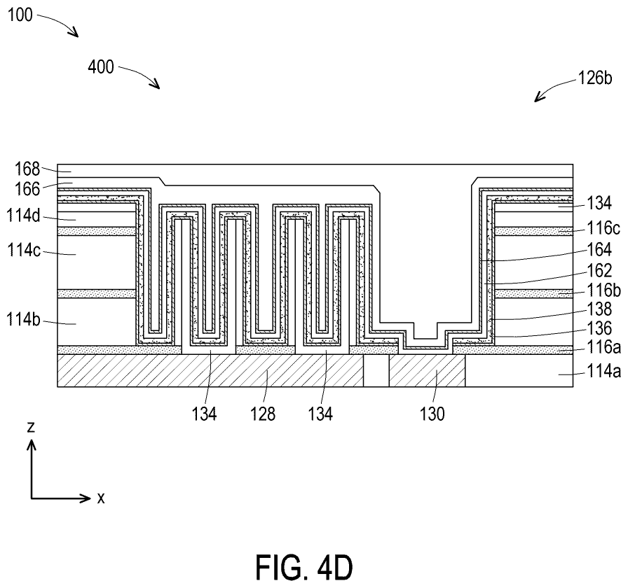

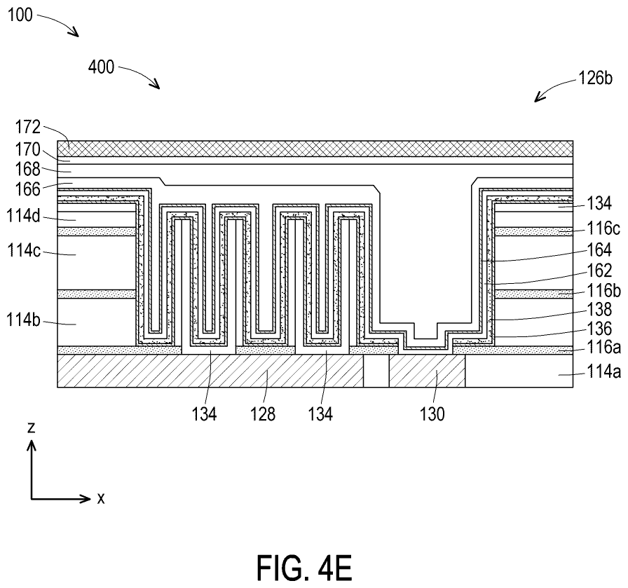

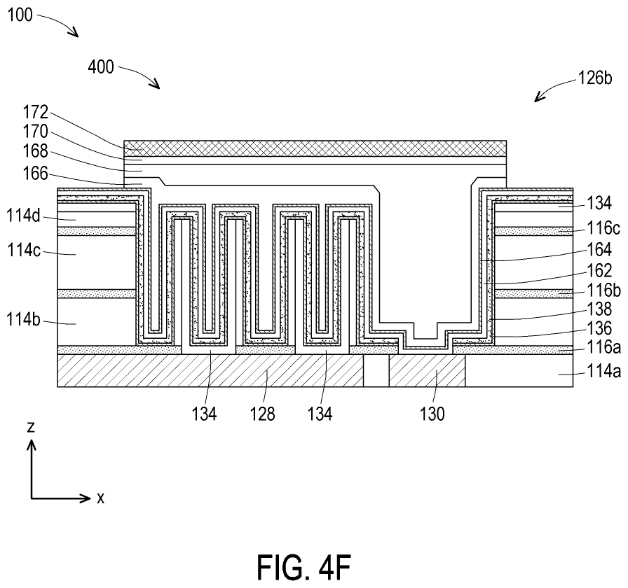

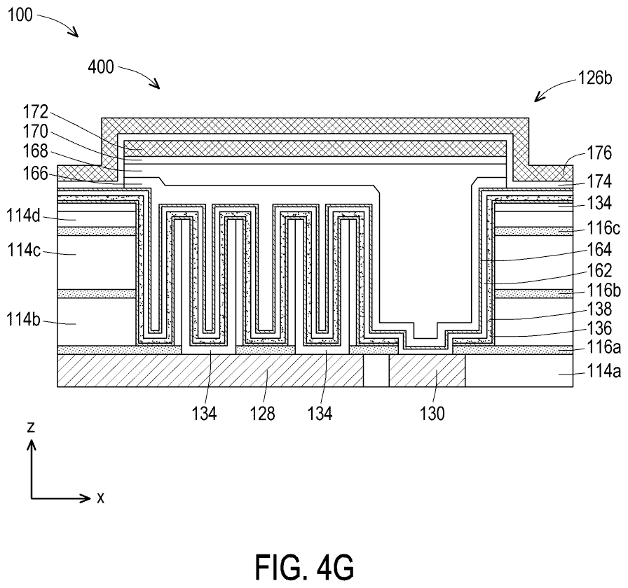

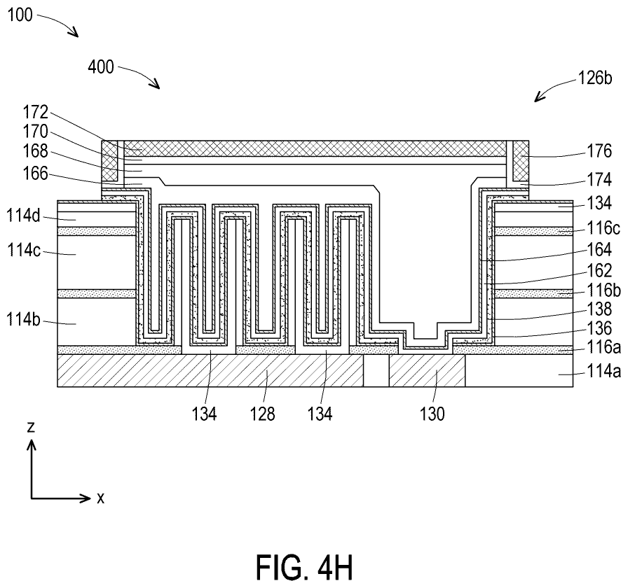

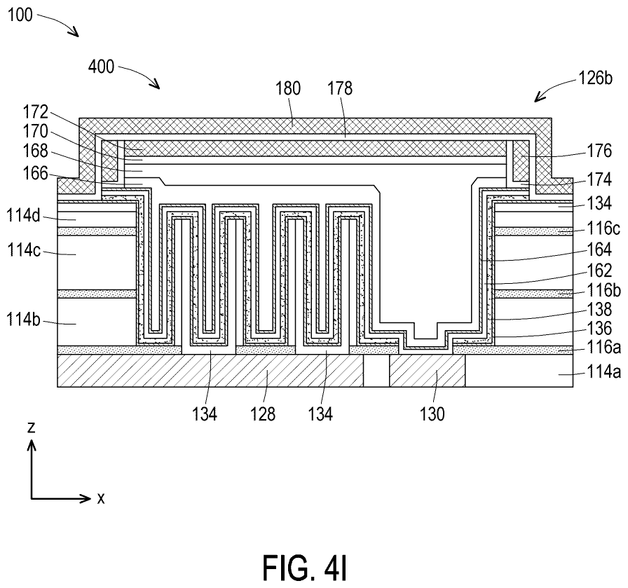

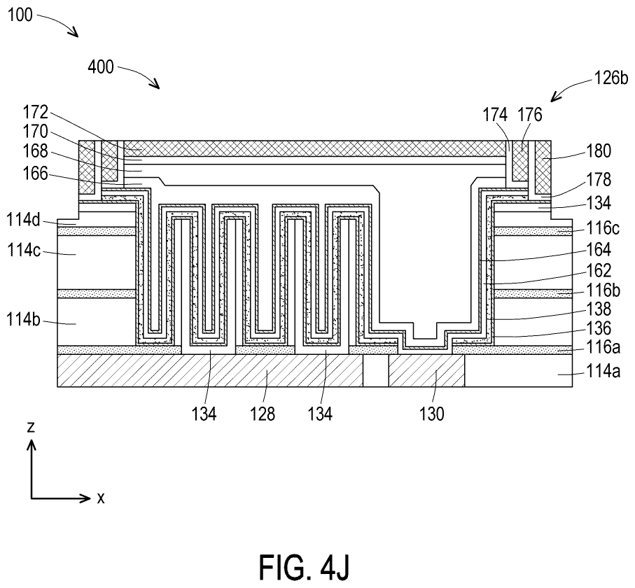

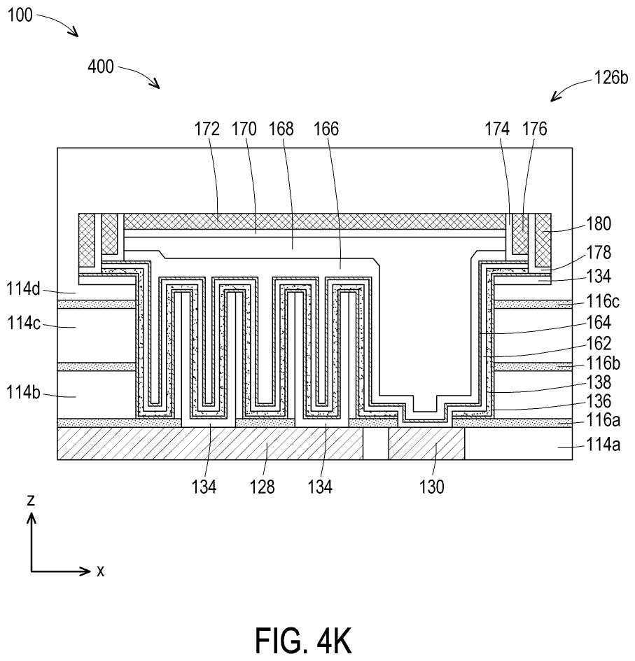

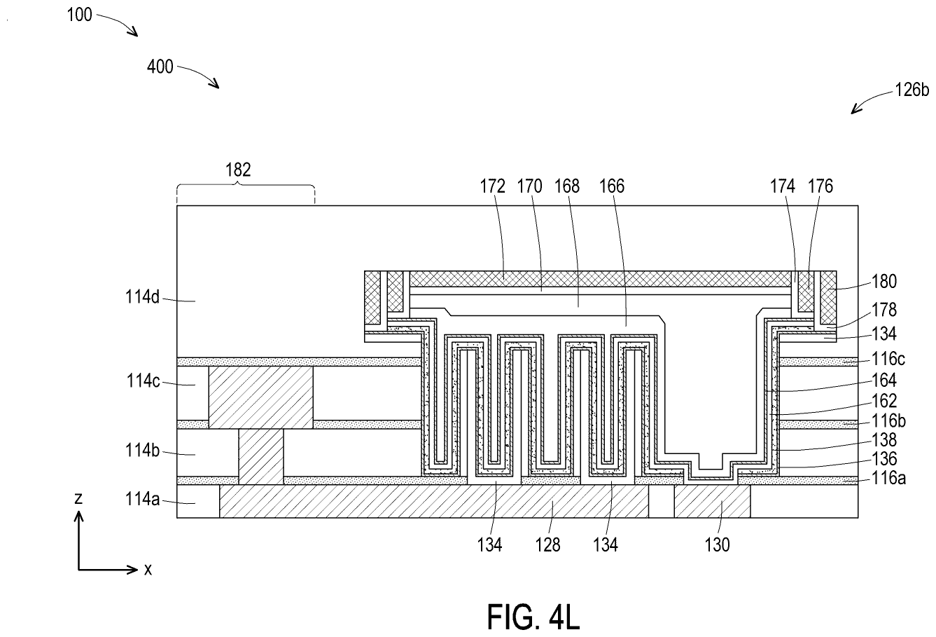

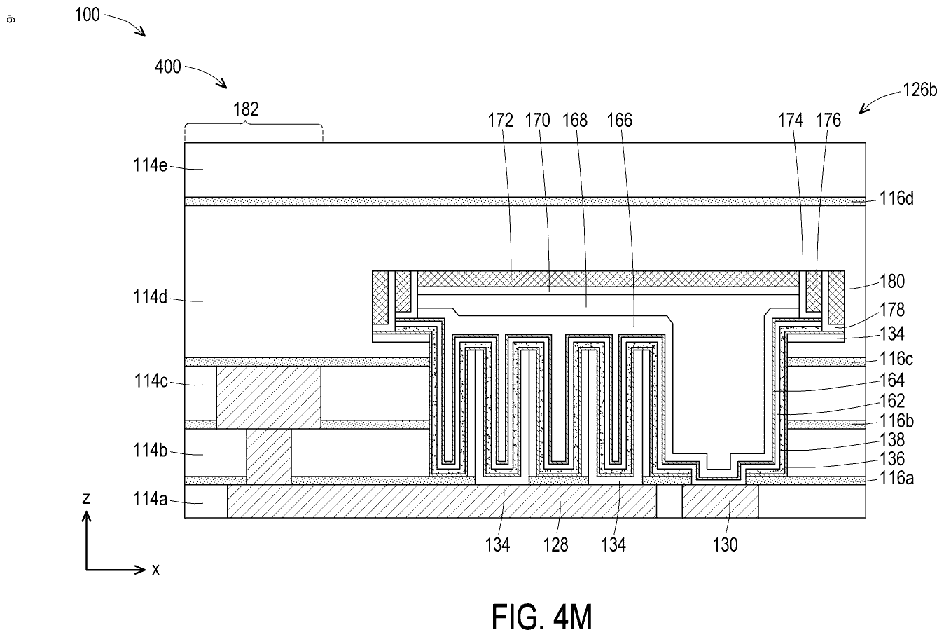

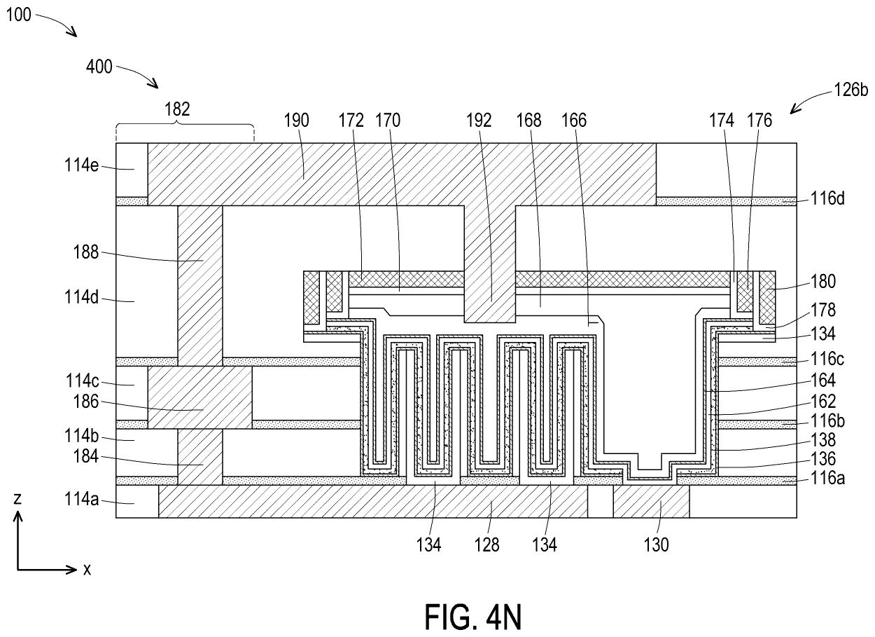

FIGS. 4A-4N are diagrams of an example implementation 400 of forming the semiconductor device 100 described herein. In some implementations, one or more of the semiconductor processing operations described in connection with FIGS. 4A-4N may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 4A, as an alternative to the example implementation 200 described in connection with FIGS. 2A-2T, and to the example implementation 300 described in connection with FIGS. 3A-3E, the trench capacitor structure 126b in the example implementation 400 includes a differently arranged top electrode layer 162 than the top electrode layer 140 of the trench capacitor structure 126a, and additional layers deposited on the top electrode layer 162. In other respects, the processing to form the trench capacitor structure 126b on the first bottom contact 128 and the second bottom contact 130 as shown in FIG. 4A, is the same or substantially the same as what is shown in FIGS. 2A-2N.

As shown in FIG. 4A, a top electrode layer 162 may be deposited on exposed surfaces of the conductive layer 138 in the trenches 202, 206, and 208, and on the exposed portion of the top surface of the second bottom contact 130 in the trench 208. The top electrode layer 162, a portion of which is formed over the second bottom contact 130, may be in physical contact with the second bottom contact 130. In the trenches 202, 206, and 208, the top electrode layer 162 is a conformal layer that conforms to the sidewalls and the bottom surfaces of the trenches 202, 206, and 208. The top electrode layer 162 may also be deposited on the top surface of the conductive layer 138 on the ILD layer 114d and on top surfaces of conductive layer 138 between and/or next to adjacent trenches 202, 206, and 208. In some implementations, a deposition tool is used to conformally deposit the top electrode layer 162 such that the top electrode layer 162 conforms to the profile of the trenches 202, 206, and 208. In some implementations, a conformal CVD technique and/or an ALD technique is used to deposit the top electrode layer 162.

In some implementations, a barrier layer may be deposited on the exposed surfaces of the conductive layer 138 in the trenches 202, 206, and 208, and on the exposed portion of the top surface of the second bottom contact 130 in the trench 208 prior to depositing the top electrode layer 162. In this case, the barrier layer may be in physical contact with the top surface of the second bottom contact 130. In some implementations, a deposition tool is used to conformally deposit the barrier layer such that the barrier layer conforms to the profile of the trenches 202, 206, and 208. In some implementations, a conformal CVD technique and/or an ALD technique is used to deposit the barrier layer. The barrier layer prevents upward migration of an electrically conductive material (e.g., copper (Cu)) of the second bottom contact 130 into the top electrode layer 162, and may include tantalum (Ta), tantalum nitride (TaN), and/or another suitable barrier material. With or without the barrier layer, the top electrode layer 162 is electrically connected to the second bottom contact 130.

As shown in FIG. 4B, a second insulator layer 164 may be deposited on exposed surfaces of the top electrode layer 162 in the trenches 202, 206, and 208. The second insulator layer 164 may also be deposited on the top surfaces of the top electrode layer 162 on the ILD layer 114d and on the top surfaces of the top electrode layer 162 between and/or next to adjacent trenches 202, 206, and 208, such that the second insulator layer 164 may be in physical contact with the top surfaces of the top electrode layer 162. In some implementations, a deposition tool is used to conformally deposit the second insulator layer 164 such that the second insulator layer 164 conforms to the profile of the trenches 202, 206, and 208. In some implementations, a conformal CVD technique and/or an ALD technique is used to deposit the insulator layer 136.

Like the insulator layer 136, the second insulator layer 164 may include one or more electrically insulating materials. In some implementations, the second insulator layer 164 includes one or more low-k dielectric materials such as silicon oxide (SiOₓ such as SiO₂). Additionally and/or alternatively, the second insulator layer 164 may include one or more high-k dielectric materials such as zirconium oxide (ZrOₓ such as ZrO₂), aluminum oxide (AlₓO_{y} such as Al₂O₃), silicon nitride (SiₓN_{y} such as Si₃N₄), yttrium oxide (YₓO_{y} such as Y₂O₃), lanthanum oxide (LaₓO_{y} such as La₂O₃), and/or hafnium oxide (HfOₓ such as HfO₂), among other examples. In some implementations, the second insulator layer 164 is a multiple-layer stack that includes a plurality of dielectric layers. For example, the insulator layer 136 may include a ZrO₂/Al₂O₃/ZrO₂ (ZAZ) layer stack.

As shown in FIG. 4C, an additional conductive layer 166 may be deposited on exposed surfaces of the second insulator layer 164 in the trenches 202, 206, and 208. As a result of the deposition of the additional conductive layer 166, trench structures 402, 404, and 406 respectively corresponding to the trenches 202, 206, and 208 are formed. Each of the trench structures 402, 404, and 406 includes a plurality of conformal layers that conform to the profile of the trenches 202, 206, and 208. In the trench structures 402, the conformal layers may include a bottom electrode layer 134, an insulator layer 136 on the bottom electrode layer 134, a conductive layer 138 on the insulator layer 136, a top electrode layer 162 on the conductive layer 138, and a second insulator layer 164 on the top electrode layer 162. In the trench structures 404 and 406, the conformal layers may include an insulator layer 136, a conductive layer 138 on the insulator layer 136, a top electrode layer 162 on the conductive layer 138, except where the top electrode layer 162 is formed on the top surface of the second bottom contact 130 in the trench structure 406, and a second insulator layer 164 on the top electrode layer 162. The trench structures 404 and 406 do not include the bottom electrode layer 134. The bottom electrode layer 134, the insulator layer 136, the conductive layer 138, the top electrode layer 162, and the second insulator layer 164 may each conform to the profile of the trench(es) 202 such that the bottom electrode layer 134, the insulator layer 136, the conductive layer 138, the top electrode layer 162, and the second insulator layer 164 conform to (e.g., are disposed along) the sidewalls and the bottom surfaces of the trench(es) 202. With the exception of the exposed top surface of the second bottom contact in the trench 208, the insulator layer 136 and the conductive layer 138 may each conform to the profile of the trenches 206 and 208 such that the insulator layer 136 and the conductive layer 138 conform to (e.g., are disposed along) the sidewalls and the bottom surfaces of the trenches 206 and 208. The top electrode layer 162 and the second insulator layer 164 also each conform to the profile of the trenches 206 and 208 such that the top electrode layer 162 and the second insulator layer 164 conform to (e.g., are disposed along) the sidewalls and the bottom surfaces of the trenches 206 and 208. The trench capacitor structure 126b further includes the additional conductive layer 166 on the second insulator layer 164. In some implementations, the additional conductive layer 166 is a fill layer that fills in the remaining areas of the trenches 202 and 206. The additional conductive layer 166 may include titanium nitride (TiN), and/or another suitable conductive material.

As shown in FIG. 4D, in the trench 208, the additional conductive layer 166 is a conformal layer that conforms to the sidewalls and the bottom surfaces of the trench 208, and a dielectric plug layer 168 is further included in the remaining areas of the trench 208. The dielectric plug layer 168 may be, for example, an oxide (e.g., a silicon oxide (SiOₓ) and/or another oxide material), and/or another type of dielectric material. A deposition tool may be used to deposit the dielectric plug layer 168 on the additional conductive layer 166 using a PVD technique, an ALD technique, a CVD technique, an oxidation technique, and/or another suitable deposition technique. In some implementations, a planarization tool may be used to perform a planarization operation such as a CMP operation to planarize the dielectric plug layer 168 after the dielectric plug layer 168 is deposited. Alternatively, a blanket etch operation may be performed to reduce a thickness of the dielectric plug layer 168 in the z-direction.

The bottom electrode layer 134, the insulator layer 136, and the top electrode layer 162 correspond to a first MIM structure of the trench capacitor structure 126b. Thus, the trench capacitor structure 126b may also be referred to as an MIM capacitor structure. The bottom electrode layer 134 (also referred to as a CBM) and the top electrode layer 162 (also referred to as a CTM) may each include one or more electrically conductive metals, one or more electrically conductive metal-containing materials, one or more electrically conductive ceramic materials, and/or other types of electrically conductive materials. Examples include tungsten (W), cobalt (Co), ruthenium (Ru), titanium (Ti), aluminum (Al), copper (Cu), gold (Au), titanium nitride (TiN), and/or tantalum nitride (TaN), among other examples. In some implementations, the bottom electrode layer 134 and the top electrode layer 162 include the same material or the same material composition. In some implementations, the bottom electrode layer 134 and the top electrode layer 162 include different materials or different material compositions.

In addition to the first MIM structure, the trench capacitor structure 126b further includes the second insulator layer 164 and the additional conductive layer 166 on the second insulator layer 164. The combination of the top electrode layer 162, the second insulator layer 164, and the additional conductive layer 166 correspond to a second MIM structure of the trench capacitor structure 126b. In comparison to the trench capacitor structure 126a in the example implementations 200 and 300, the addition of the second insulator layer 164 and the additional conductive layer 166 in the trench capacitor structure 126b of the example implementation 400 may increase capacitance by approximately 2 times.

As shown in FIG. 4E, a first upper dielectric layer 170 is deposited on the dielectric plug layer 168, and a second upper dielectric layer 172 is deposited on the first upper dielectric layer 170. The first upper dielectric layer 170 may be, for example, a nitride (a silicon oxynitride (SiON), and/or another nitride material), and/or another type of dielectric material. The second upper dielectric layer 172 may be, for example, a nitride (a silicon nitride (SiₓN_{y}), and/or another nitride material), and/or another type of dielectric material. A deposition tool may be used to deposit the first upper dielectric layer 170 on the dielectric plug layer 168, and the second upper dielectric layer 172 on the first upper dielectric layer 170 using a PVD technique, an ALD technique, a CVD technique, an oxidation technique, and/or another suitable deposition technique. In some implementations, a planarization tool may be used to perform a planarization operation such as a CMP operation to planarize the first upper dielectric layer 170 after the first upper dielectric layer 170 is deposited and/or to planarize the second upper dielectric layer 172 after the second upper dielectric layer 172 is deposited.

As shown in FIG. 4F, side portions of the second upper dielectric layer 172, the first upper dielectric layer 170, the dielectric plug layer 168, and the additional conductive layer 166 are removed to result in a patterned trench capacitor structure 126b, where part of the second insulator layer 164 is exposed. In some implementations, a mask layer is formed on part of the second upper dielectric layer 172, and an etch operation is performed to etch portions not covered by the mask layer. The etch operation may include a dry etch operation (e.g., a plasma-based etch operation, a gas-based etch operation), a wet chemical etch operation, and/or another type of etch operation. Gas etchants such as, for example, oxygen (O₂), argon (Ar) and/or fluorine-based gases can be used. The fluorine-based etchants may include a carbon fluoride-based (CFₓ) gas etchant such as a carbon tetrafluoride (CF₄) gas etchant.

As shown in FIG. 4G, a third upper dielectric layer 174 is deposited on the second upper dielectric layer 172, around sides of the first and second upper dielectric layers 170 and 172, and of the dielectric plug layer 168, and onto exposed top surfaces of the second insulator layer 164. A fourth upper dielectric layer 176 is conformally deposited on the third upper dielectric layer 174. The third upper dielectric layer 174 may be, for example, an oxide (e.g., a silicon oxide (SiOₓ) and/or another oxide material), and/or another type of dielectric material. The fourth upper dielectric layer 176 may be, for example, a nitride (a silicon nitride (SiₓN_{y}), and/or another nitride material), and/or another type of dielectric material. A deposition tool may be used to deposit the third and fourth upper dielectric layers 174 and 176 using a PVD technique, an ALD technique, a CVD technique, an oxidation technique, and/or another suitable deposition technique.

As shown in FIG. 4H, a blanket etch operation is performed to remove portions of the third and fourth upper dielectric layers 174 and 176, and parts of the second insulator layer 164, the top electrode layer 162, and the conductive layer 138, resulting in parts of the insulator layer 136 being exposed. In some implementations, the blanket etch operation includes a dry etch operation (e.g., a plasma-based etch operation, a gas-based etch operation), a wet chemical etch operation, and/or another type of etch operation.

As shown in FIG. 4I, a fifth upper dielectric layer 178 is deposited on the second upper dielectric layer 172, on part of the third upper dielectric layer 174, around sides of the third and fourth upper dielectric layers 174 and 176, and onto exposed top surfaces of the insulator layer 136. A sixth upper dielectric layer 180 is conformally deposited on the fifth upper dielectric layer 178. The fifth upper dielectric layer 178 may be, for example, an oxide (e.g., a silicon oxide (SiOₓ) and/or another oxide material), and/or another type of dielectric material. The sixth upper dielectric layer 180 may be, for example, a nitride (a silicon nitride (SiₓN_{y}), and/or another nitride material), and/or another type of dielectric material. A deposition tool may be used to deposit the fifth and sixth upper dielectric layers 178 and 180 using a PVD technique, an ALD technique, a CVD technique, an oxidation technique, and/or another suitable deposition technique.

As shown in FIG. 4J, a blanket etch operation is performed to remove portions of the fifth and sixth upper dielectric layers 178 and 180, and underlying portions of the insulator layer 136, of the bottom electrode layer 134, and of the ILD layer 114d. In some implementations, the blanket etch operation includes a dry etch operation (e.g., a plasma-based etch operation, a gas-based etch operation), a wet chemical etch operation, and/or another type of etch operation.

As shown in FIG. 4K, one or more deposition tools are used to deposit an additional portion of the ILD layer 114d to increase a vertical height of the ILD layer 114d in the z-direction. The one or more deposition tools may be used to deposit the additional portion of the ILD layer 114d using a PVD technique, an ALD technique, a CVD technique, an oxidation technique, and/or another suitable deposition technique.

FIG. 4L illustrates a wider view in the x-direction of the semiconductor device 100 in the example implementation 400, which shows a peripheral area 182 including an interconnect structure 184 and a metallization structure 186. FIG. 4L further illustrates that, in some implementations, a planarization tool may be used to planarize the additional portion of the ILD layer 114d after the additional portion of the ILD layer 114d is deposited. As shown in FIG. 4L, metallization structures 186, and interconnect structure (e.g., via) 184 are formed in the peripheral area 182 laterally adjacent to the trench capacitor structure 126b in the x-direction.

A deposition tool, an exposure tool, a developer tool, an etch tool, a planarization tool, a plating tool, and/or another semiconductor processing tool may be used to perform various operations to form the metallization structure 186, and to form the interconnect structure 184. In some implementations, the first bottom contact 128, the second bottom contact, the metallization structure 186, and the interconnect structure 184 may be formed in a plurality of layers. For example, an ILD layer 114 and an ESL 116 may be formed (e.g., using one or more deposition tools and/or one or more planarization tools), recesses may be formed in and/or through the ILD layer 114 and the ESL 116 (e.g., using an exposure tool, a developer tool, and/or an etch tool), and the layer (e.g., the M0 layer) including the first bottom contact 128 and the second bottom contact, may be formed in the ILD layer 114a and the ESL 116a (e.g., using one or more deposition tools and/or one or more planarization tools). Another ILD layer 114b and another ESL 116b may be formed, and the layer (e.g., the V0 layer) including interconnect structure 184 may be formed in the ILD layer 114b and the ESL 116b. The remaining layers may be formed in a similar manner.

One or more deposition tools may be used to deposit the metallization structure 186, the interconnect structure 184, the first bottom contact 128, and/or the second bottom contact 130 using a PVD technique, an ALD technique, a CVD technique, an electroplating technique (e.g., an electro-chemical plating technique), and/or another suitable deposition technique. In some implementations, a planarization tool may be used to planarize the metallization structure 186, the interconnect structures 184, the first bottom contact 128, and/or the second bottom contact 130 after the metallization structure 186, the interconnect structure 184, the first bottom contact 128, and/or the second bottom contact 130 are deposited.

As shown in FIG. 4M, one or more deposition tools are used to deposit ESL 116d and ILD layer 114e. In this way, the ILD layers 114 and ESLs 116 may be arranged in the z-direction in the semiconductor device 100. One or more deposition tools may be used to deposit each of the ILD layers 114 and each of the ESLs 116 using a PVD technique, an ALD technique, a CVD technique, an oxidation technique, and/or another suitable deposition technique. In some implementations, a planarization tool may be used to planarize the ILD layers 114 and/or the ESLs 116 after the ILD layers 114 and/or the ESLs 116 are deposited.

As shown in FIG. 4N, metallization structure 190 and interconnect structures (e.g., vias) 188 and 192 are formed. The interconnect structure 188 is formed in the peripheral area 182 laterally adjacent to the trench capacitor structure 126b in the x-direction, and the metallization structure 190 is formed in the peripheral area 182 and over the trench capacitor structure 126b in the z-direction. The interconnect structure 192 extends from the metallization structure 190 through the ILD layer 114d, the second upper dielectric layer 172, the first upper dielectric layer 170, and the dielectric plug layer 168 into the additional conductive layer 166, so that the interconnect structure 192 physically contacts the additional conductive layer 166.

A deposition tool, an exposure tool, a developer tool, an etch tool, a planarization tool, a plating tool, and/or another semiconductor processing tool may be used to perform various operations to form the metallization structure 190, and to form the interconnect structures 188 and 192. One or more deposition tools may be used to deposit the metallization structure 190, and the interconnect structures 188 and 192 using a PVD technique, an ALD technique, a CVD technique, an electroplating technique (e.g., an electro-chemical plating technique), and/or another suitable deposition technique. In some implementations, a planarization tool may be used to planarize the metallization structure 190, and/or the interconnect structures 188 and 192, after the metallization structure 190 and/or the interconnect structures 188 and 192 are deposited.

As indicated above, FIGS. 4A-4N are provided as an example. Other examples may differ from what is described with regard to FIGS. 4A-4N.

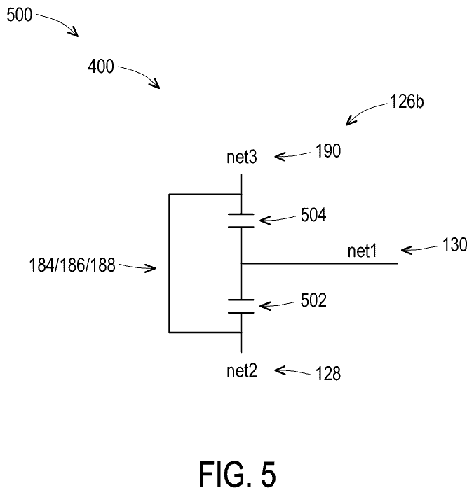

FIG. 5 is a circuit diagram 500 of the example implementation 400 of the trench capacitor structure 126b described in connection with FIG. 4N. As shown in FIG. 5, the trench capacitor structure 126b includes a first MIM capacitor 502 and a second MIM capacitor 504.

The bottom electrode layer 134, the insulator layer 136, and the top electrode layer 162 correspond to the first MIM capacitor 502, and the top electrode layer 162, the second insulator layer 164, and the additional conductive layer 166 correspond to the second MIM capacitor 504. In comparison to the trench capacitor structure 126a, the addition of the second MIM capacitor 504 in the trench capacitor structure 126b of the example implementation 400 may increase capacitance by approximately 2 times, as per the following equation:

$${C}_{Total} = {C}_{1} + {C}_{2}$$

where C_{Total} refers to the total capacitance, C₁ is the capacitance of the first MIM capacitor 502, and C₂ is the capacitance of the second MIM capacitor 504. The first bottom contact 128 (net2) is connected to the bottom electrode layer 134, which serves as the bottom electrode for the first MIM capacitor 502. The first bottom contact 128 (net2) is also connected to the metallization structure 190 (net3) through the combination of the metallization structure 186 and the interconnect structures 184 and 188. The metallization structure 190 is connected to the additional conductive layer 166, which serves as the top electrode for the second MIM capacitor 504, through the interconnect structure 192. The second bottom contact 130 (net1) is connected to the top electrode layer 162, which serves as the top electrode for the first MIM capacitor 502 and the bottom electrode for the second MIM capacitor 504.

As indicated above, FIG. 5 is provided as an example. Other examples may differ from what is described with regard to FIG. 5.

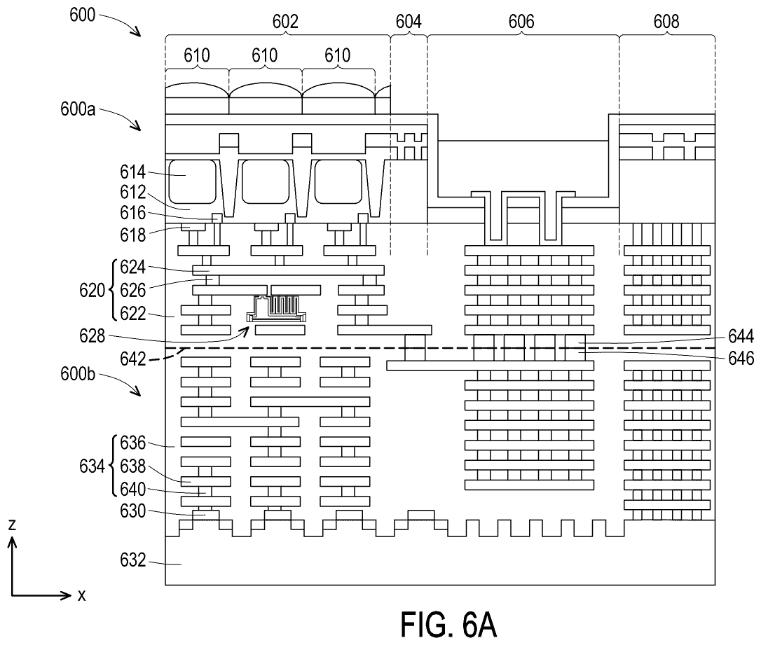

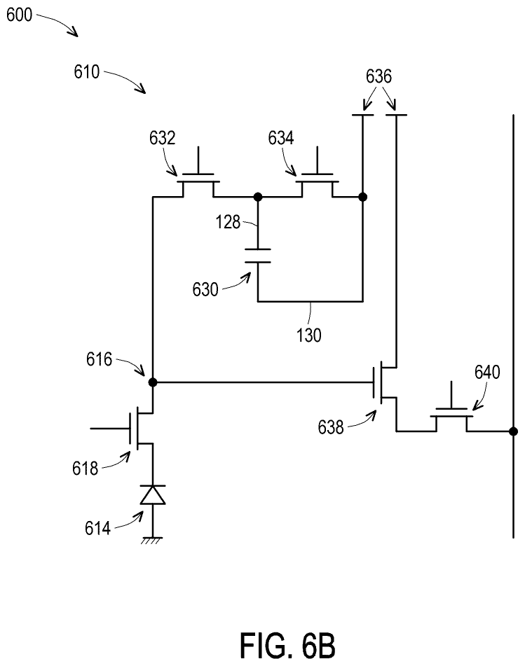

FIG. 6A is a diagram of an example semiconductor device 600 described herein. The semiconductor device 600 may include an example of a three-dimensional image sensor (e.g., a 3D CMOS image sensor). The semiconductor device 600 may be configured to be deployed in various implementations, such as digital cameras, video recorders, night-vision cameras, automotive sensors and cameras, and/or other types of light-sensing implementations.

As shown in FIG. 6A, the semiconductor device 600 may include a three-dimensional stacked structure in which a semiconductor structure 600a and a semiconductor structure 600b are stacked and vertically arranged in the semiconductor device 600. The semiconductor structures 600a and 600b may each be semiconductor dies, semiconductor chips, and/or other types of semiconductor structures that are formed on wafers, cut into dies, and then bonded together.

The semiconductor structure 600a may be an image sensor die that includes a pixel sensor array 602. The semiconductor structure 600a may further include a black level correction (BLC) region 604, a bonding pad region 606, and/or a seal ring region 608, among other examples. The pixel sensor array 602 may include a plurality of pixel sensors 610 arranged in an array. The pixel sensors 610 may be configured to sense incident light and convert photons of the incident light to a photocurrent. The pixel sensors 610 may be included in a device layer 612 of the semiconductor structure 600a. The pixel sensors 610 may each include one or more photodiodes 614 that are configured to generate a photocurrent based on photons of incident light. The pixel sensors 610 may further include a floating diffusion node 616 in the device layer 612 that is configured to temporarily store the photocurrent generated by an associated pixel sensor 610, and may each include a transfer gate 618 that is configured to control the flow of photocurrent from a photodiode 614 to a floating diffusion node 616. The pixel sensors 610 may be formed by one or more semiconductor processing tools using various semiconductor processing techniques, such as photolithography, etching, deposition, CMP, and/or ion implantation, among other examples.

The BLC region 604 includes a metal shielding layer over a portion of the device layer 612 so that a baseline measurement of current in the device layer 612 in the BLC region 604 can be performed to determine the dark current (e.g., the current in the device layer 612 that is generated from sources other than incident light, such as heat) of the pixel sensor array 602, so that the black level of the pixel sensor array 602 can be adjusted to compensate for the dark current. The bonding pad region 606 may include one or more conductive bonding pads (or e-pads) and/or metallization layers through which electrical connections between the semiconductor structure 600a and outside devices and/or external packaging may be established. The seal ring region 608 may include an arrangement of metallization structures and interconnect structures to provide structural rigidity for the semiconductor structure 600a and to protect the semiconductor structure 600a from ingress of humidity and other contaminants.

As further shown in FIG. 6A, the semiconductor structure 600a may include an interconnect layer 620 under the device layer 612. The interconnect layer 620 may include a dielectric region 622 that includes one or more dielectric layers (e.g., ILD layers, intermetal dielectric (IMD) layers, ESLs) and an arrangement of metallization structures 624 and interconnect structures 626 in the dielectric region 622.

As further shown in FIG. 6A, one or more overflow capacitors 628 may be included in the interconnect layer 620. The overflow capacitor(s) 628 may be structurally implemented as the trench capacitor structure 126a or the trench capacitor structure 126b illustrated and described herein. An overflow capacitor 628 may be electrically coupled to a floating diffusion node 616 of a pixel sensor 610 and may be configured to store overflow photocurrent from the floating diffusion node 616.

The semiconductor structure 600b may be a processor die, an application-specific integrated circuit (ASIC) die, and/or another type of semiconductor die that includes integrated circuit devices 630 in a device layer 632. The integrated circuit devices 630 may include transistors, capacitors, and/or other types of integrated circuit devices that are configured to process signals generated by the semiconductor die 600a.

As further shown in FIG. 6A, the semiconductor structure 600b may include an interconnect layer 634 above the device layer 632. The interconnect layer 634 may include a dielectric region 636 that includes one or more dielectric layers (e.g., ILD layers, intermetal dielectric (IMD) layers, ESLs) and an arrangement of metallization structures 638 and interconnect structures 640 in the dielectric region 636.

As further shown in FIG. 6A, the semiconductor structures 600a and 600b may be bonded together at a bonding interface 642 between the interconnect layers 620 and 634.

Bonding structures 644 (e.g., bonding pads, bonding vias) on the semiconductor structure 600a may be bonded together with bonding structures 644 (e.g., bonding pads, bonding vias) on the semiconductor structure 600b in metal-to-metal bonds at the bonding interface 642. Additionally and/or alternatively, the dielectric region 622 of the semiconductor structure 600a and the dielectric region 636 of the semiconductor structure 600b may be bonded together in dielectric-to-dielectric bonds at the bonding interface 642.

FIG. 6B is a diagram of an example circuit for a pixel sensor 610 described herein. The pixel sensor 610 may include a front side pixel sensor (e.g., a pixel sensor that is configured to receive photons of light from a front side of a sensor die), a back side pixel sensor (e.g., a pixel sensor that is configured to receive photons of light from a back side of a sensor die), and/or another type of pixel sensor.

As shown in an example circuit in FIG. 6B, a pixel sensor 610 includes a photodiode 614 that may be configured to sense and/or accumulate incident light (e.g., light directed toward the pixel sensor 610) and convert photons of the incident light to a photocurrent. The magnitude of the photocurrent may be based on the number of photons (e.g., the intensity of the incident light) collected in the photodiode 614. Thus, the accumulation of photons in the photodiode 614 generates a build-up of electrical charge that represents the intensity or brightness of the incident light (e.g., a greater amount of charge may correspond to a greater intensity or brightness, and a lesser amount of charge may correspond to a lower intensity or brightness).

The photodiode 614 is electrically connected with a transfer gate 618. The transfer gate 618 is configured to control the transfer of the photocurrent from the photodiode to a floating diffusion node 616. The transfer gate 618 may be selectively switched by applying a transfer voltage (Vₜₓ) to the transfer gate 618. In some implementations, the transfer voltage being applied to the transfer gate 618 causes a leakage path (e.g., a buried channel) to form between the photodiode 614 and the floating diffusion node 616 across the transfer gate 618, which enables the photocurrent to travel along the leakage path to the floating diffusion node 616. In some implementations, the transfer voltage being removed from the transfer gate 618 (or the absence of the transfer voltage) causes the leakage path to be removed, such that the photocurrent cannot pass from the photodiode 614 to the floating diffusion node 616.

The circuit for the pixel sensor 610 may further include a reset gate 634. The reset gate 634 is electrically connected to a voltage source 636. The reset gate 634 may be controlled to selectively apply a reset voltage (Vᵣₛₜ) to the floating diffusion node 616 from the voltage source 636. The transfer gate 618 and the reset gate 634 may be electrically coupled with the floating diffusion node 616 such that the reset voltage is applied to the floating diffusion node 616 to “reset” the floating diffusion node 616 (e.g., by draining any residual charge in the floating diffusion node 616) prior to activation of the transfer gate 618 to transfer a photocurrent from the photodiode 614 to the floating diffusion node 616.

The pixel sensor 610 may be a lateral overflow integration capacitor (LOFIC) pixel sensor that includes an overflow gate 632 and an overflow capacitor 630. The overflow capacitor 630 may be electrically coupled to the floating diffusion node 616 through the overflow gate 632 such that photocurrent may be transferred from the floating diffusion node 616 to the overflow capacitor 630 for temporary storage. The overflow gate 632 may selectively control the flow of photocurrent to and/or from the overflow capacitor 630. This enables additional photocurrent to be transferred to the floating diffusion node 616 from the photodiode 614 without causing the pixel sensor 610 to reach saturation, which increases the full well capacity and the dynamic range of the pixel sensor 610.

The photocurrent may be used to apply a floating diffusion voltage (Vfd) to a source follower gate 638 of the circuit of the pixel sensor 610. This permits the photocurrent to be observed without removing or discharging the photocurrent from the floating diffusion node 616 and/or from the overflow capacitor 630. The reset gate 634 may instead be used to remove or discharge the photocurrent from the floating diffusion node 616 and/or from the overflow capacitor 630. A capacitor top metal (CTM) layer of the overflow capacitor 630 is coupled to a drain side of the reset gate 634 and to a drain voltage (V_{dd}) by the second bottom contact 130. A CBM layer of the overflow capacitor 630 is coupled to a source side of the reset gate 634 by the first bottom contact 128.

To apply the floating diffusion voltage to the source follower gate 638, the transfer gate 618 may be switched off (e.g., so that the photocurrent does not flow back into the photodiode 614) and the overflow gate 632 may be switched on. This configuration enables the photocurrent stored in floating diffusion node 616 and in the overflow capacitor 630 to be used to apply the floating diffusion voltage to the source follower gate 638.

The source follower gate 638 functions as a high impedance amplifier for the pixel sensor 610. The source follower gate 638 provides a voltage-to-current conversion of the floating diffusion voltage. The output of the source follower gate 638 is electrically connected with a row select gate 640, which is configured to control the flow of the photocurrent to external circuitry. The row select gate 640 is controlled by selectively applying a select voltage (V_{di}) to the gate of the row select gate 640. This permits the photocurrent to flow to an output of the pixel sensor 610.

As indicated above, FIGS. 6A and 6B are provided as examples. Other examples may differ from what is described with regard to FIGS. 6A and 6B.

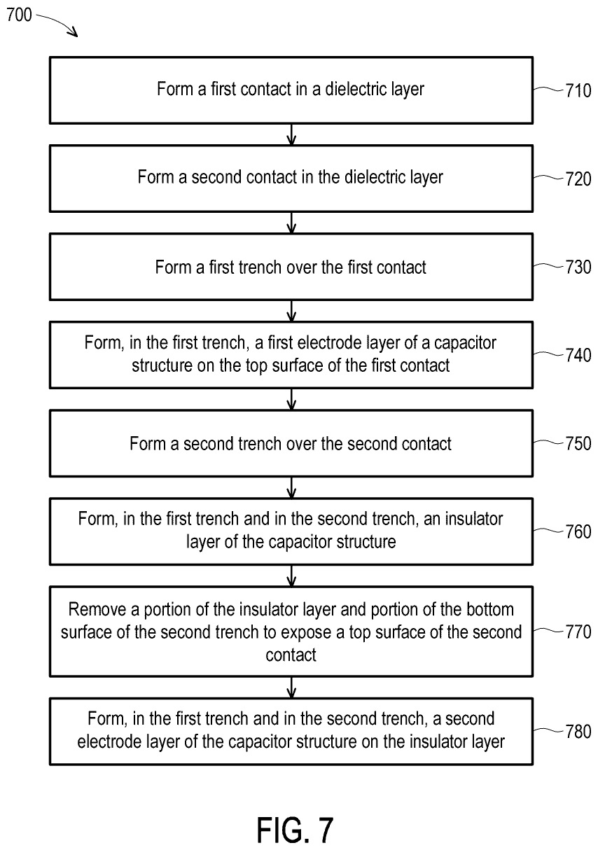

FIG. 7 is a flowchart of an example process 700 associated with forming a semiconductor device. In some implementations, one or more process blocks of FIG. 7 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 7, process 700 may include forming a first contact in a dielectric layer (block 710). For example, one or more semiconductor processing tools may be used to form a first contact (e.g., first bottom contact 128) in a dielectric layer (e.g., ILD layer 114a), as described herein.

As further shown in FIG. 7, process 700 may include forming a second contact in the dielectric layer (block 720). For example, one or more semiconductor processing tools may be used to form a second contact (e.g., second bottom contact 130) in the dielectric layer, as described herein. In some implementations, the second contact is adjacent to and spaced apart from the first contact. In some implementations, the first contact and the second contact (e.g., the first bottom contact 128 and the second bottom contact 130) are formed by the same deposition process. For example, the operations of block 710 and 720 may be performed concurrently or may be performed as part of the same step. In some implementations, the first contact and the second contact (e.g., the first bottom contact 128 and the second bottom contact 130) are formed by separate deposition processes. For example, the operations of block 710 and 720 may be performed sequentially as part of different steps.

As further shown in FIG. 7, process 700 may include forming a first trench over the first contact (block 730). For example, one or more semiconductor processing tools may be used to form a first trench (e.g., trench 202) over the first contact, as described herein. In some implementations, a top surface of the first contact is exposed at a bottom of the first trench.

As further shown in FIG. 7, process 700 may include forming, in the first trench, a first electrode layer of a capacitor structure on the top surface of the first contact (block 740). For example, one or more semiconductor processing tools may be used to form, in the first trench, a first electrode layer (e.g., bottom electrode layer 134) of a capacitor structure (e.g., trench capacitor structure 126a or trench capacitor structure 126b) on the top surface of the first contact, as described herein.

As further shown in FIG. 7, process 700 may include forming a second trench over the second contact (block 750). For example, one or more semiconductor processing tools may be used to form a second trench (e.g., trench 208) over the second contact, as described herein.

As further shown in FIG. 7, process 700 may include forming, in the first trench and in the second trench, an insulator layer of the capacitor structure (block 760). For example, one or more semiconductor processing tools may be used to form, in the first trench and in the second trench, an insulator layer (e.g., insulator layer 136) of the capacitor structure, as described herein. In some implementations, the insulator layer is on the first electrode layer in the first trench, and on a bottom surface of the second trench.

As further shown in FIG. 7, process 700 may include removing a portion of the insulator layer and portion of the bottom surface of the second trench to expose a top surface of the second contact (block 770). For example, one or more semiconductor processing tools may be used to remove a portion of the insulator layer and portion of the bottom surface of the second trench to expose a top surface of the second contact, as described herein.

As further shown in FIG. 7, process 700 may include forming, in the first trench and in the second trench, a second electrode layer of the capacitor structure on the insulator layer (block 780). For example, one or more semiconductor processing tools may be used to form, in the first trench and in the second trench, a second electrode layer (e.g., top electrode layer 140 or top electrode layer 162) of the capacitor structure on the insulator layer, as described herein. In some implementations, a portion of the second electrode layer is formed on the top surface of the second contact.

Process 700 may include additional implementations, such as any single implementation or any combination of implementations described below and/or in connection with one or more other processes described elsewhere herein.

In a first implementation, process 700 includes forming, in the first trench and in the second trench, an additional insulator layer (e.g., second insulator layer 164) on the second electrode layer, where the first electrode layer is formed along sidewalls and a bottom surface of the first trench, and where the insulator layer, the second electrode layer and the additional insulator layer are formed along the sidewalls and the bottom surface of the first trench, and along sidewalls and the bottom surface of the second trench.

In a second implementation, alone or in combination with the first implementation, process 700 includes forming, in the first trench and in the second trench, a conductive layer (e.g., additional conductive layer 166) on the additional insulator layer (e.g. second insulator layer 164), and forming a third contact (e.g., metallization structure 190) over the capacitor structure, where a via (e.g., interconnect structure 192) is formed between the third contact and the conductive layer to electrically connect the third contact to the conductive layer.

In a third implementation, alone or in combination with one or more of the first and second implementations, the third contact is electrically connected to the first contact.

In a fourth implementation, alone or in combination with one or more of the first through third implementations, the third contact is electrically connected to the first contact through at least one via (e.g. interconnect structure 184 and/or interconnect structure 188) formed between the third contact and the first contact and on a side of the capacitor structure.

In a fifth implementation, alone or in combination with one or more of the first through fourth implementations, a conductive layer (e.g. protective conductive layer 132) is formed along opposite sidewalls of the first trench on opposite sides of the first electrode layer.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, a top electrode layer of a capacitor structure of a pixel sensor is connected to a bottom contact (e.g., as opposed to a top connection) of an interconnect layer of a semiconductor device. The bottom contact is located at the bottom of the capacitor structure and connects the top electrode layer to a reset voltage source and to a reset transistor of the pixel sensor without the use of additional vias, metallization layers, and/or other conductive interconnect structures that extend alongside the capacitor structure. As a result, the lateral footprint of the capacitor structure can be increased, which increases capacitor area of the capacitor structure.

The use of the bottom contact also prevents plasma charge damage to the top electrode layer in that the top electrode layer is formed on the bottom contact as opposed to a top connection being formed on the top electrode layer. Thus, the plasma charge damage that might otherwise be caused during an etching process to form a recess for the top connection is avoided. The connection of the top electrode layer to the bottom contact also facilitates implementation of a local reset function for the pixel sensor and other pixel sensors in a pixel sensor array of the semiconductor device. For example, the bottom connection can be part of an existing metallization loop or part of an added metallization layer to connect capacitor structures of the pixel sensors to the reset voltage source so that the capacitor structures can be reset locally with a reduced RC time constant, resulting in faster capacitor reset speeds and increased frame rates in comparison to other pixel sensor arrays. In some implementations, in addition to providing a bottom contact structure, capacitance is further increased by using a trench capacitor structure with a second MIM structure on a first MIM structure.

As described in greater detail above, some implementations described herein provide a semiconductor device. The semiconductor device includes one or more dielectric layers. The semiconductor device includes a capacitor structure in the one or more dielectric layers. The capacitor structure includes one or more trench structures. The capacitor structure includes a first electrode layer in the one or more trench structures, an insulator layer on the first electrode layer in the one or more trench structures, and a second electrode layer on the insulator layer in the one or more trench structures. The semiconductor device includes a first conductive contact under the one or more trench structures in a first direction. The first electrode layer is electrically connected to the first conductive contact. The semiconductor device includes a second conductive contact laterally adjacent to a side of the first conductive contact in a second direction approximately perpendicular to the first direction, where the second electrode layer is electrically connected to the second conductive contact, and where at least a portion of the second electrode layer is over the second conductive contact.

As described in greater detail above, some implementations described herein provide a method. The method includes forming a first contact in a dielectric layer. The method includes forming a second contact in the dielectric layer, where the second contact is adjacent to and spaced apart from the first contact. The method includes forming a first trench over the first contact, where a top surface of the first contact is exposed at a bottom of the first trench. The method includes forming, in the first trench, a first electrode layer of a capacitor structure on the top surface of the first contact. The method includes forming a second trench over the second contact. The method includes forming, in the first trench and in the second trench, an insulator layer of the capacitor structure, where the insulator layer is on the first electrode layer in the first trench, and on a bottom surface of the second trench. The method includes removing a portion of the insulator layer and portion of the bottom surface of the second trench to expose a top surface of the second contact. The method includes forming, in the first trench and in the second trench, a second electrode layer of the capacitor structure on the insulator layer, where a portion of the second electrode layer is formed on the top surface of the second contact.

As described in greater detail above, some implementations described herein provide a semiconductor device. The semiconductor device includes a capacitor structure. The capacitor structure includes a first conductive layer on sidewalls and a bottom surface of a trench structure, a second conductive layer in the trench structure, and an insulator layer between the first conductive layer and the second conductive layer. The semiconductor device includes a first bottom contact under the bottom surface of the trench structure, where the first conductive layer is on the first bottom contact. The semiconductor device includes a second bottom contact laterally adjacent to the first bottom contact, where the second conductive layer is on the second bottom contact.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
one or more dielectric layers;
a capacitor structure in the one or more dielectric layers,
wherein the capacitor structure comprises:
one or more trench structures;
a first electrode layer in the one or more trench structures;
an insulator layer on the first electrode layer in the one or more trench structures; and
a second electrode layer on the insulator layer in the one or more trench structures;
a first conductive contact under the one or more trench structures in a first direction,
wherein the first electrode layer is electrically connected to the first conductive contact; and
a second conductive contact laterally adjacent to a side of the first conductive contact in a second direction approximately perpendicular to the first direction,
wherein the second electrode layer is electrically connected to the second conductive contact, and
wherein at least a portion of the second electrode layer is over the second conductive contact.

2. The semiconductor device of claim 1, wherein the capacitor structure further comprises one or more additional trench structures laterally adjacent to the one or more trench structures in the second direction; and
wherein the one or more additional trench structures comprise the insulator layer and the second electrode layer on the insulator layer in the one or more additional trench structures.

3. The semiconductor device of claim 2, wherein the second electrode layer is electrically connected to the second conductive contact at a bottom of the one or more additional trench structures.

4. The semiconductor device of claim 2, wherein the second electrode layer is in contact with the second conductive contact at a bottom of the one or more additional trench structures.

5. The semiconductor device of claim 2, wherein the insulator layer is on a dielectric layer of the one or more dielectric layers at a bottom of the one or more additional trench structures.

6. The semiconductor device of claim 1, wherein the capacitor structure further comprises a conductive layer between the insulator layer and the second electrode layer in the one or more trench structures.

7. The semiconductor device of claim 1, wherein the capacitor structure further comprises a conductive layer laterally adjacent to the one or more trench structures in the second direction; and
wherein the conductive layer is on a side of the first electrode layer.

8. The semiconductor device of claim 7, wherein the conductive layer is on a top surface of a dielectric layer of the one or more dielectric layers.

9. The semiconductor device of claim 1, wherein the capacitor structure further comprises an additional insulator layer on the first electrode layer in the one or more trench structures.

10. The semiconductor device of claim 9, wherein the capacitor structure further comprises a conductive layer on the additional insulator layer in the one or more trench structures.

11. A method, comprising:
forming a first contact in a dielectric layer;
forming a second contact in the dielectric layer,
wherein the second contact is adjacent to and spaced apart from the first contact;
forming a first trench over the first contact,
wherein a top surface of the first contact is exposed at a bottom of the first trench;
forming, in the first trench, a first electrode layer of a capacitor structure on the top surface of the first contact;
forming a second trench over the second contact;
forming, in the first trench and in the second trench, an insulator layer of the capacitor structure,
wherein the insulator layer is on the first electrode layer in the first trench, and on a bottom surface of the second trench;
removing a portion of the insulator layer and portion of the bottom surface of the second trench to expose a top surface of the second contact; and
forming, in the first trench and in the second trench, a second electrode layer of the capacitor structure on the insulator layer,
wherein a portion of the second electrode layer is formed on the top surface of the second contact.

12. The method of claim 11, further comprising forming, in the first trench and in the second trench, an additional insulator layer on the second electrode layer,
wherein the first electrode layer is formed along sidewalls and a bottom surface of the first trench; and
wherein the insulator layer, the second electrode layer and the additional insulator layer are formed along the sidewalls and the bottom surface of the first trench, and along sidewalls and the bottom surface of the second trench.

13. The method of claim 12, further comprising:
forming, in the first trench and in the second trench, a conductive layer on the additional insulator layer; and
forming a third contact over the capacitor structure,
wherein a via is formed between the third contact and the conductive layer to electrically connect the third contact to the conductive layer.

14. The method of claim 13, wherein the third contact is electrically connected to the first contact.

15. The method of claim 14, wherein the third contact is electrically connected to the first contact through at least one via formed between the third contact and the first contact and on a side of the capacitor structure.

16. The method of claim 11, wherein a conductive layer is formed along opposite sidewalls of the first trench on opposite sides of the first electrode layer.

17. A semiconductor device, comprising:
a capacitor structure, comprising:
a first conductive layer on sidewalls and a bottom surface of a trench structure;
a second conductive layer in the trench structure; and
an insulator layer between the first conductive layer and the second conductive layer;
a first bottom contact under the bottom surface of the trench structure,
wherein the first conductive layer is on the first bottom contact; and
a second bottom contact laterally adjacent to the first bottom contact,
wherein the second conductive layer is on the second bottom contact.

18. The semiconductor device of claim 17, wherein the second conductive layer is on the second bottom contact at a bottom of an additional trench structure; and
wherein the additional trench structure is laterally adjacent to the trench structure.

19. The semiconductor device of claim 18, further comprising an additional insulator layer on the second conductive layer,
wherein the additional insulator layer is disposed along the sidewalls and the bottom surface of the trench structure, and along sidewalls and a bottom surface of the additional trench structure.

20. The semiconductor device of claim 17, wherein the first bottom contact and the second bottom contact are coplanar or substantially coplanar with each other.
